(19) United States
(12) Patent Application Publication
(10) Pub. No.: US 2016/0142069 A1
(43) Pub. Date: May 19, 2016

(54) Multi-path, series-switched, passively-summed digital-to-analog converter

(71) Applicant: John Howard La Grou, Placerville, CA (US)

(72) Inventor: John Howard La Grou, Placerville, CA (US)

(21) Appl. No.: 15/004,891

(22) Filed: Jan. 23, 2016

Related U.S. Application Data
(63) Continuation-in-part of application No. 14/935,363, filed on Nov. 6, 2015.
(60) Provisional application No. 62/199,955, filed on Jul. 31, 2015.
(60) Provisional application No. 62/188,884, filed on Jul. 6, 2015.
(60) Provisional application No. 62/106,219, filed on Jan. 22, 2015.
(60) Provisional application No. 62/076,560, filed on Nov. 7, 2014.

(51) Int. Cl. H03M 1/08; H03M 1/66

(52) U.S. Cl. CPC H03M 1/08; H03M 1/66

(57) ABSTRACT

A digital-to-analog converter which minimizes noise and optimizes dynamic range by apportioning a least significant bits portion of an incoming digital signal to a low-path circuit and a most significant bits portion of the incoming digital signal to a high-path circuit. The low-path circuit has a low-path digital-to-analog converter, which feeds a low-path amplifier, which feeds a low-path resistive element, which feeds an output node. The high-path circuit has a high-path digital-to-analog converter, which feeds a high-path amplifier, which feeds a high-path resistive element when a high-path switching element is closed, which feeds an output node. The output node is a simple electrical connection of the outputs of the low-path and high-path resistive elements. The high-path switching element is closed when the incoming digital signal has an amplitude above a switching threshold level. Parameters of the circuit, including the sizes of the least significant bits portion and most significant bits portion of the incoming digital signal, are selected such that the switching threshold level is significantly above the noise level produced by the high-path circuit thereby providing psychoacoustic masking of noise produced by the high-path circuit.

### CROSS-REFERENCE TO RELATED APPLICATIONS

The present application is based on and claims the priority of non-provisional patent application Ser. No. 14/935,363 filed Nov. 6, 2015 by John Howard La Grou entitled “Multi-path, series-switched, passively-summed digital-to-analog converter,” which is based on and claims the priority of provisional patent application Ser. No. 62/199,955 filed Jul. 31, 2015 by John La Grou entitled “Process and system for the digital-to-analog conversion of signals, continuation of earlier filing,” provisional patent application Ser. No. 62/188,884 filed Jul. 6, 2015 by John La Grou entitled “Process and system for the digital-to-analog conversion of signals, continuation of earlier filing,” provisional patent application Ser. No. 62/106,219 filed Jan. 22, 2015 by John La Grou entitled “Process and system for the digital-to-analog conversion of signals, continuation of earlier filing,” and provisional patent application Ser. No. 62/076,560 filed Nov. 7, 2014 by John La Grou entitled “Process and system for the digital-to-analog conversion of signals.”

### TECHNICAL FIELD

The present invention relates to electronic devices, more particularly to digital-to-analog converters, and still more particularly to D-A conversion systems and methods which utilize multiple D-A converters and/or provide low noise and/or high dynamic range.

### BACKGROUND OF THE INVENTION

Audio DAC (digital-to-analog conversion) technology has improved at a steady pace over the past three decades. Two critical and interrelated parameters, broadband self-noise and dynamic range, have improved at an average pace of roughly 0.7 dB per year over the last 30 years, or a one-bit performance improvement roughly every 8 years since the 1980s. The present invention seeks to greatly improve both dynamic range and self-noise of digital-to-analog conversion. The present invention improves today's DAC best dynamic range performance by roughly 4 bits while reducing broadband self-noise by roughly 15 dB. To achieve these significant performance improvements, according to the present invention a number of novel design techniques are combined and optimized, including DSP-controlled multi-path parallel conversion, ADC multi-path monitor and DSP compensation, DSP-managed passive summing and high-range series switching. Furthermore, according to the present invention ADC (analog-to-digital conversion) is used for measuring path levels in consort with DSP calibration of said path levels in a passively summed multi-path DAC topology. Furthermore, according to the present invention multiple pre-adapted digital input signals may be processed according to alternative embodiments of the present invention.

Therefore, it is an object of the present invention to provide method and apparatus for digital-to-audio conversion having low noise and large dynamic range.

More particularly, it is an object of the present invention to provide method and apparatus for digital-to-audio conversion having low noise and large dynamic range utilizing circuitry that separately processes a most significant bits portion and a least significant bits portion of an input digital signal, particularly where noise in the analog output signal is reduced by switching out the high-path circuitry when the input signal has a sufficiently low level, and outputs from the low- and high-path circuitry are passively summed.

It is another object of the present invention to provide method and apparatus for digital-to-audio conversion which utilizes circuit behavior monitoring and feedback to improve performance characteristics.

Additional objects and advantages of the invention will be set forth in the description which follows, and will be apparent from the description or may be learned from the practice of the invention. The objects and advantages of the invention may be realized and obtained by means of the instrumentalities and combinations particularly pointed out in the claims.

### SUMMARY OF THE INVENTION

The present invention is directed to an apparatus for conversion of an input digital signal to an output analog signal having a maximum output level. The input digital signal is nominally a signal of K bits. The apparatus includes a bit grouping providing system which takes the input digital signal and produces a low-path digital signal of L bits and a high-path digital signal of H bits, where L+H is greater than or equal to J, and J is a number of bits of said input digital signal utilized by said bit divider where J is less than or equal to K. The apparatus includes a low-path digital-to-analog converter for digital inputs of R_{L} bits or less, the low-path digital signal being bit shift mapped to an input of the low-path digital-to-analog converter where L is less than or equal to R_{L}, and where the L bits of the low-path digital signal are level shift mapped upwards by Lₛ bits where L+Lₛ≦R_{L}. The low-path digital-to-analog converter produces a low-path digital-to-analog converter output signal. Similarly, the apparatus includes a high-path digital-to-analog converter for digital inputs of R_{H} bits, the high-path digital signal being digitally level shifted to an input of said high-path digital-to-analog converter by a bit shift of Hₛ bits such that (K−Hₛ)≦R_{H} and (K−H−Hₛ)≧0. The high-path digital-to-analog converter produces a high-path digital-to-analog converter output signal. The apparatus further includes a low-path attenuator which attenuates the low-path digital-to-analog converter output signal to produce an attenuated low-path analog signal, and a high-path amplifier which amplifies the high-path digital-to-analog converter output signal to produce an amplified high-path signal having a maximum level equal to the maximum output level of the apparatus. The apparatus further includes a passive summing node which, if a signal level characteristic of the input digital signal exceeds a threshold level, sums a penultimate low-path signal derived from the attenuated low-path analog signal and a penultimate high-path signal derived from the amplified high-path signal to produce the output analog signal and, if the signal level characteristic of the input digital signal does not exceed said threshold level, utilizes a means to reduce access of noise from the high-path amplifier to the passive summing node.

The present invention is also directed to an apparatus for conversion of an input digital signal to an output analog signal having a maximum output level, where the input digital signal is nominally a signal of K bits. The apparatus includes a bit grouping providing system which takes the input digital signal and produces a low-path digital signal of L bits, a middle-path digital signal of M bits, and a high-path digital signal of H bits, where L+M+H is greater than or equal to J, and J is a number of bits of said input digital signal utilized by said bit divider, where J is less than or equal to K. The apparatus includes a low-path digital-to-analog converter for digital inputs of R_{L} bits or less. The low-path digital signal is digitally level shifted by the bit grouping providing system to an input of the low-path digital-to-analog converter, where L is less than or equal to R_{L}, such that the L bits of the low-path digital signal are level shift mapped by Lₛ bits, where L+Lₛ≦R_{L}. The low-path digital-to-analog converter produces a low-path digital-to-analog converter output signal. The apparatus includes a middle-path digital-to-analog converter for digital inputs of R_{M} bits or less. The middle-path digital signal is digitally level shifted by the bit grouping providing system to an input of the middle-path digital-to-analog converter, where M is less than or equal to R_{M}. The middle-path digital-to-analog converter produces a middle-path digital-to-analog converter output signal. The apparatus also includes a high-path digital-to-analog converter for digital inputs of R_{H} bits or less. The high-path digital signal is digitally level shifted by the bit grouping providing system to an input of the high-path digital-to-analog converter, where H is less than or equal to R_{H}, such that the H bits of the high-path digital signal are level shift mapped downwards by Lₛ bits, where (J−Hₛ)≦R_{H}. The high-path digital-to-analog converter produces a high-path digital-to-analog converter output signal. The apparatus further includes a low-path attenuator which attenuates the low-path digital-to-analog converter output signal to produce an attenuated low-path analog signal, and a high-path amplifier which amplifies the high-path digital-to-analog converter output signal to produce an amplified high-path signal having a maximum level equal to the maximum output level. The apparatus further includes a passive summing node which, if a signal level characteristic of the input digital signal exceeds a first threshold level, sums a penultimate low-path signal derived from the attenuated low-path analog signal, a penultimate middle-path signal derived from the middle-path digital-to-analog converter output signal, and a penultimate high-path signal derived from the amplified high-path signal to produce the output analog signal. If the signal level characteristic of the input digital signal exceeds a second threshold level but not the first threshold level, the apparatus sums the penultimate low-path signal derived from said attenuated low-path analog signal and the penultimate middle-path signal derived from the middle-path digital-to-analog converter output signal to produce the output analog signal, and utilizes a means to reduce access of noise from the high-path amplifier to the passive summing node. And if the signal level characteristic of said input digital signal does not exceed the second threshold level, the apparatus utilizes a means to reduce access of noise from the middle-path digital-to-analog converter output signal and the high-path amplifier to the passive summing node.

The present invention is also directed to an apparatus for conversion of an input digital signal to an output analog signal having a maximum output level, where the input digital signal is nominally a signal of K bits. The apparatus includes a bit grouping providing system which takes the input digital signal and produces a low-path digital signal of L bits, a number n of middle-path digital signals of M₁, . . . , Mₙ bits, and a high-path digital signal of H bits, where L+M₁+ . . . +Mₙ+H is greater than or equal to J, and J is a number of bits of the input digital signal utilized by said bit divider, where J is less than or equal to K. The apparatus has a low-path digital-to-analog converter for digital inputs of R_{L} bits or less, the low-path digital signal being digitally level shifted to an input of the low-path digital-to-analog converter, where L is less than or equal to R_{L}, such that the L bits of the low-path digital signal are level shift mapped upwards by Lₛ bits where L+Lₛ≦R_{L}. The low-path digital-to-analog converter producing a low-path digital-to-analog converter output signal. Furthermore, the apparatus has n middle-path digital-to-analog converters for digital inputs of R_{M1}, . . . , R_{Mn} bits or less, the middle-path digital signals being digitally level shifted to inputs of the middle-path digital-to-analog converter where M₁ . . . Mₙ are less than or equal to R_{M1}, . . . , R_{Mn}, respectively. The middle-path digital-to-analog converters produce middle-path digital-to-analog converter output signals. Furthermore, the apparatus has a high-path digital-to-analog converter for digital inputs of R_{H} bits, the high-path digital signal being digitally level shifted downwards to an input of the high-path digital-to-analog converter by a bit shift of Hₛ bits such that (J−Hₛ)≦R_{H}. The high-path digital-to-analog converter produces a high-path digital-to-analog converter output signal. The apparatus includes a low-path attenuator which attenuates the low-path digital-to-analog converter output signal to produce an attenuated low-path analog signal, and a high-path amplifier which amplifies the high-path digital-to-analog converter output signal to produce an amplified high-path signal having a maximum level equal to the maximum output level. The apparatus has a passive summing node which, if a signal level characteristic of the input digital signal exceeds a highest threshold level, sums a penultimate low-path signal derived from the attenuated low-path analog signal, penultimate middle-path signals derived from the middle-path digital-to-analog converter output signals, and a penultimate high-path signal derived from the amplified high-path signal to produce the output analog signal. If the signal level characteristic of the input digital signal does not exceed a lowest threshold level, the apparatus utilizes a means to reduce access of noise from the middle-path digital-to-analog converter output signals and the high-path amplifier to the passive summing node.

### BRIEF DESCRIPTION OF DRAWINGS

The accompanying figures, which are incorporated in and form a part of this specification, illustrate embodiments of the invention and, together with the description given above and the detailed description of the preferred embodiments given below, serve to explain the principles of the invention.

FIG. 1A shows a schematic of a digital-to-analog converter which separates the processing of the most significant bits (MSB) and the least significant bits (LSB).

FIG. 1B shows the separation of the bits of a 24-bit signal into a group of 13 least significant bits (LSB) and 13 most significant bits (MSB).

FIG. 2A shows a schematic of a digital-to-analog converter which separates the processing of the low-range signal, mid-range signal and high-range signal.

FIG. 2B shows the separation of the bits of a 32-bit signal into a group of 12 low-range bits, 13 mid-range bits, and 11 high-range bits by a digital signal processor.

FIG. 3A shows a two-path digital-to-analog conversion circuit according to the present invention.

FIG. 3B shows signal and noise levels at various points in the circuit of FIG. 3A where the entire 32-bit digital input signal is utilized.

FIG. 3C shows signal and noise levels at various points in the circuit of FIG. 3A where 30 bits of the 32-bit digital input signal is utilized.

FIG. 4 shows the separation of the bits of a 32-bit signal into a group of 12 low-range bits, 13 mid-range bits, and 11 high-range bits prior to input to a digital signal processor.

FIG. 5 shows a schematic of system which utilizes the present invention in the processing of sound captured by a low sound-pressure level microphone and a high sound-pressure level microphone.

FIG. 6A shows a three-path digital-to-analog conversion circuit according to the present invention.

FIG. 6B shows signal and noise levels at various points in the circuit of FIG. 6A.

FIG. 6C shows an exemplary division of a 32 bit digital input signal into five digital portions.

FIG. 6D shows an instance where maximal numbers of bits are directed to the mid-path and high-path digital-to-analog converters.

FIG. 7 shows a calibration process for the circuit of FIG. 3A.

FIG. 8 shows a calibration process for the circuit of FIG. 6A.

FIG. 9 shows signal levels at various points in the circuit of FIG. 6A when there is a −6 dB shift in levels relative to those shown in FIG. 6B.

FIG. 10 shows the interrelationship of key operational parameters.

### DETAILED DESCRIPTION OF THE INVENTION

Prior art multi-path digital-to-analog converters (DACs) exhibit performance limitations due to a number of factors. The present invention improves certain performance characteristics, the primary objectives being the reduction of systemic noise and an increase in dynamic range.

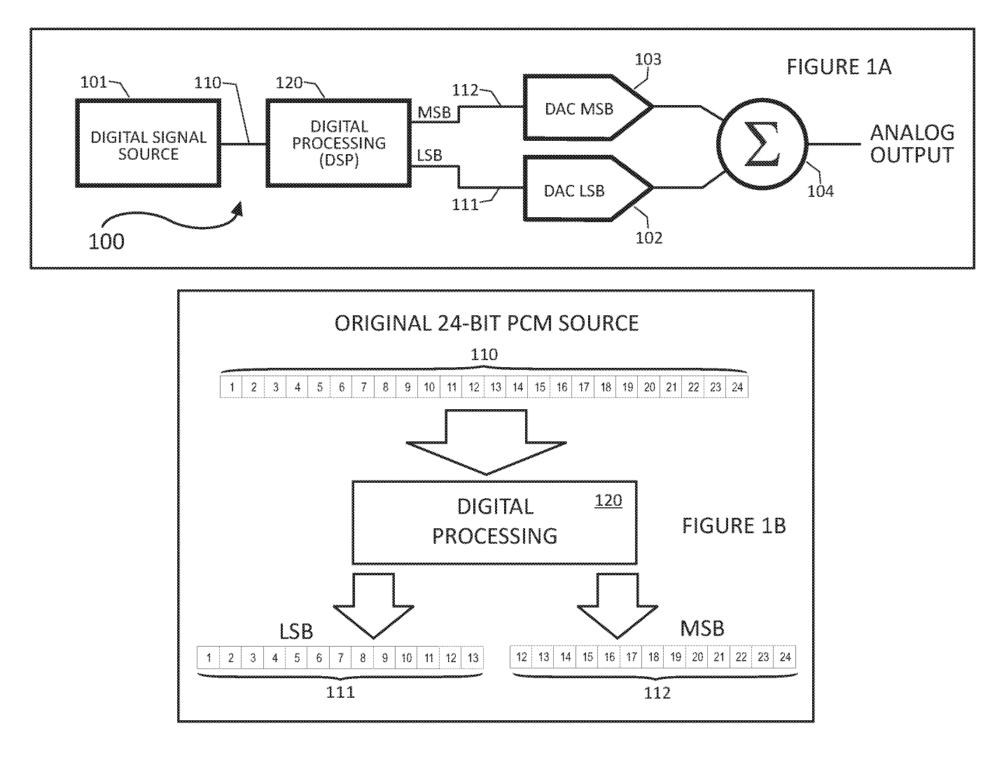

The circuit (100) shown in FIG. 1A shows the fundamental process and system on which the current invention is built upon. The circuit (100) of FIG. 1A performs a multi-range D-A conversion of a signal (101) (typically a PCM-encoded signal) which is sent (110) to a digital signal processor (DSP) (120) or any digital processing circuit capable of the necessary digital functions described herein. The DSP (120) is designed or programmed to separate the inputted digital signal (110) into multiple sections. For instance, as shown in FIG. 1B, the DSP (120) separates a 24-bit digital word (110) into two smaller contiguous data packets (111) and (112). The number of bits shown in the lowest significant bits (LSB) packet (111) and the most significant bits (MSB) packet (112) packets is an arbitrary example, and may vary depending upon specific design criteria. Each data packet (111) and (112) is sent to a digital-to-analog converter (DAC) (102) and (103), respectively, which is an integrated circuit or other manner or style of digital-to-analog converter. In particular, the lower DAC (102) is dedicated to the least significant bits (LSB) packet (111) and the upper DAC (103) is dedicated to the most significant bits (MSB) packet (112). As depicted in FIG. 1B, some bit overlap (which is facilitated by cross-fading, level-shifting or other adjustments, as described in detail below) may be used. In particular, in the example of FIG. 1B the 12^{th} and 13^{th} bits of the input signal (110) are allocated to both the LSB packet (111) and the MSB packet (112). The output signal of each DAC (102) and (103) can be differential or single-ended, but is typically differential in integrated circuit DACs. The analog output of each DAC (102) and (103) is sent to an analog summing node (104) which recombines the outputs of the LSB DAC (102) and the MSB DAC (103) into a single analog signal.

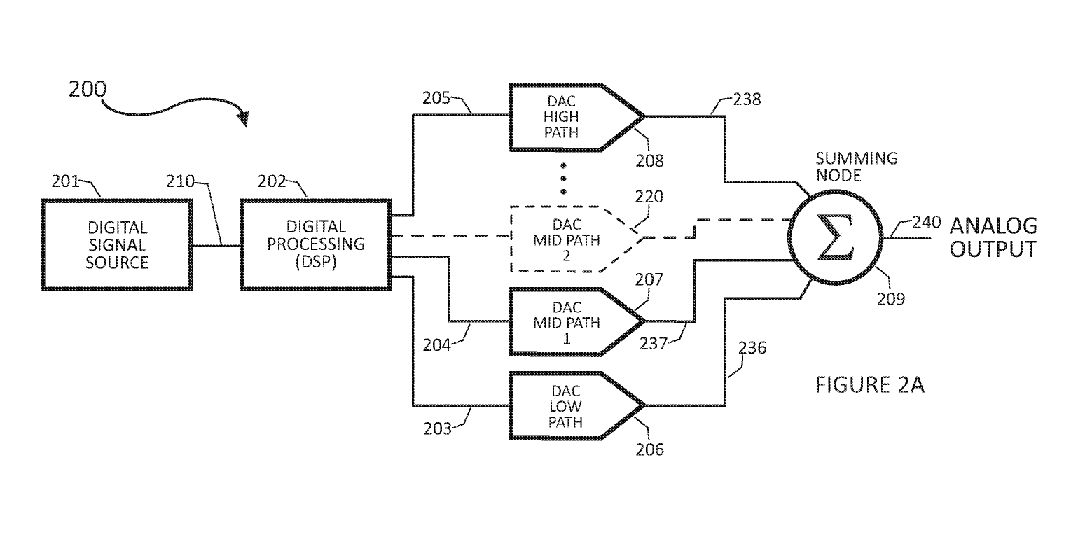

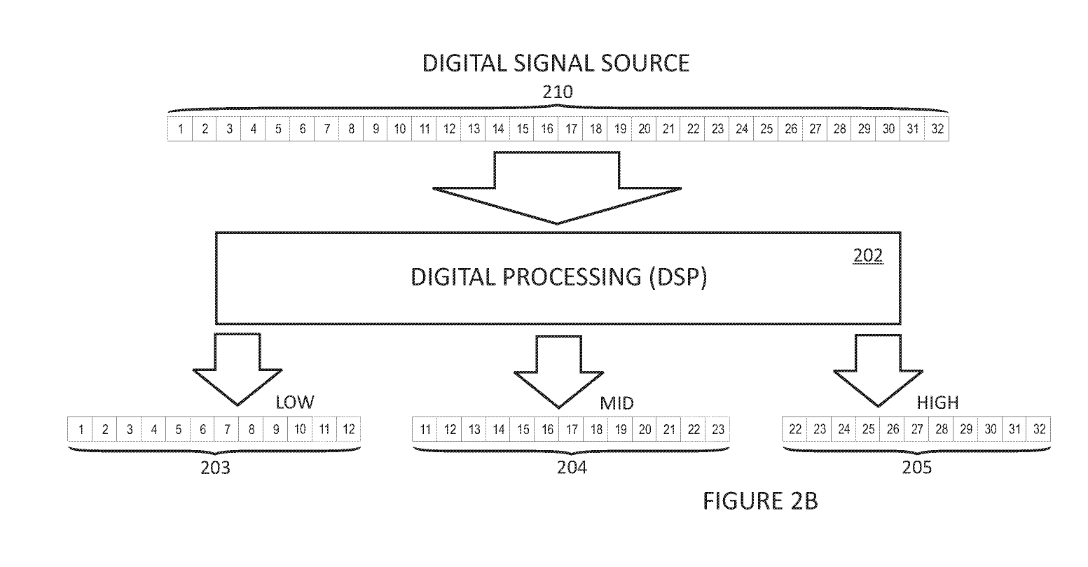

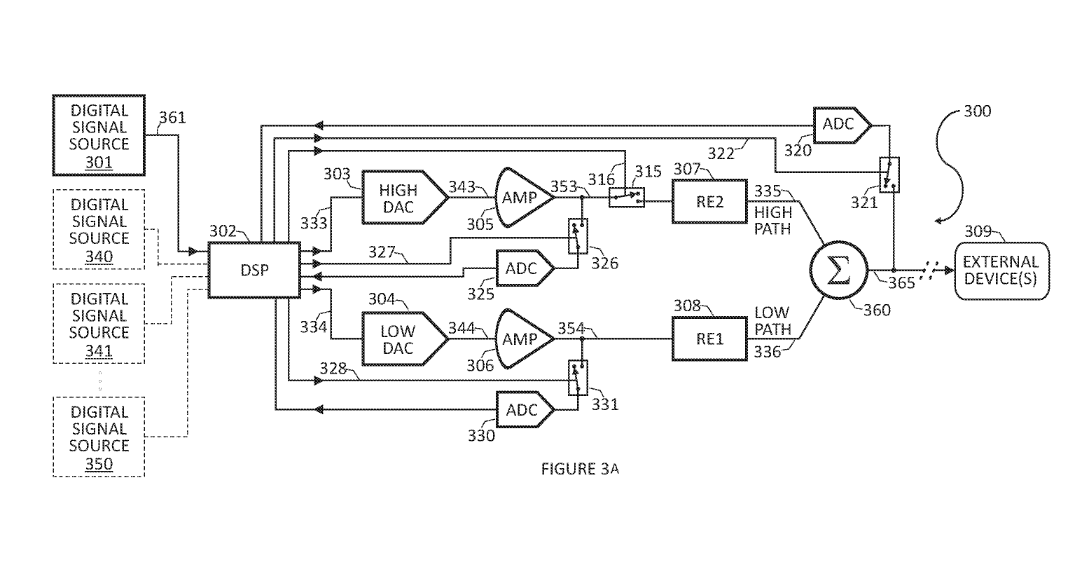

The method and system of the present invention is not limited to a two stage topology, but can be realized with any number of stages as is suggested by the dotted-line mid-level DAC (220) unit shown in FIG. 2A. For instance, as shown in the embodiment of FIGS. 2A and 2B, a 32-bit PCM input signal (210) is separated into a three-stage topology. In FIG. 2A, the DSP (202) separates the 32-bit digital word (210) in the incoming data stream into three smaller packets: a low-range packet (203), a mid-range packet (204), and high-range packet (205). The number of bits shown in the low-, mid-, and high-range packets (203), (204) and (205) is an arbitrary example, and may vary depending upon specific design criteria. Each data packet (203), (204) and (205) is sent to a DAC (206), (207) and (208), respectively, which is an integrated circuit or other manner or style of DAC irrespective of topology, whether signed, unsigned, twos-complement, or otherwise. As depicted in FIG. 2B, some bit overlap (which is facilitated by dynamic optimization, cross-fading, level-shifting or other adjustments, as described in detail below) may be used. In particular, in the example of FIG. 2B the 11^{th} and 12^{th} bits of the input signal (210) are allocated to both the low-range packet (203) and the mid-range packet (204), and the 22^{nd} and 23rd bits of the input signal (210) are allocated to both the mid-range packet (204) and the high-range packet (205). The output signal of each DAC (206), (207) and (208) can be differential or single-ended, but is typically differential in integrated circuit DACs. The analog output (236), (237) and (238) of each DAC (206), (207) and (208), respectively, is sent to an analog summing node (209) which combines the low-, mid-, and high-range analog signals into a single analog output signal (240).

### A Preferred Two-Path Embodiment According to the Present Invention

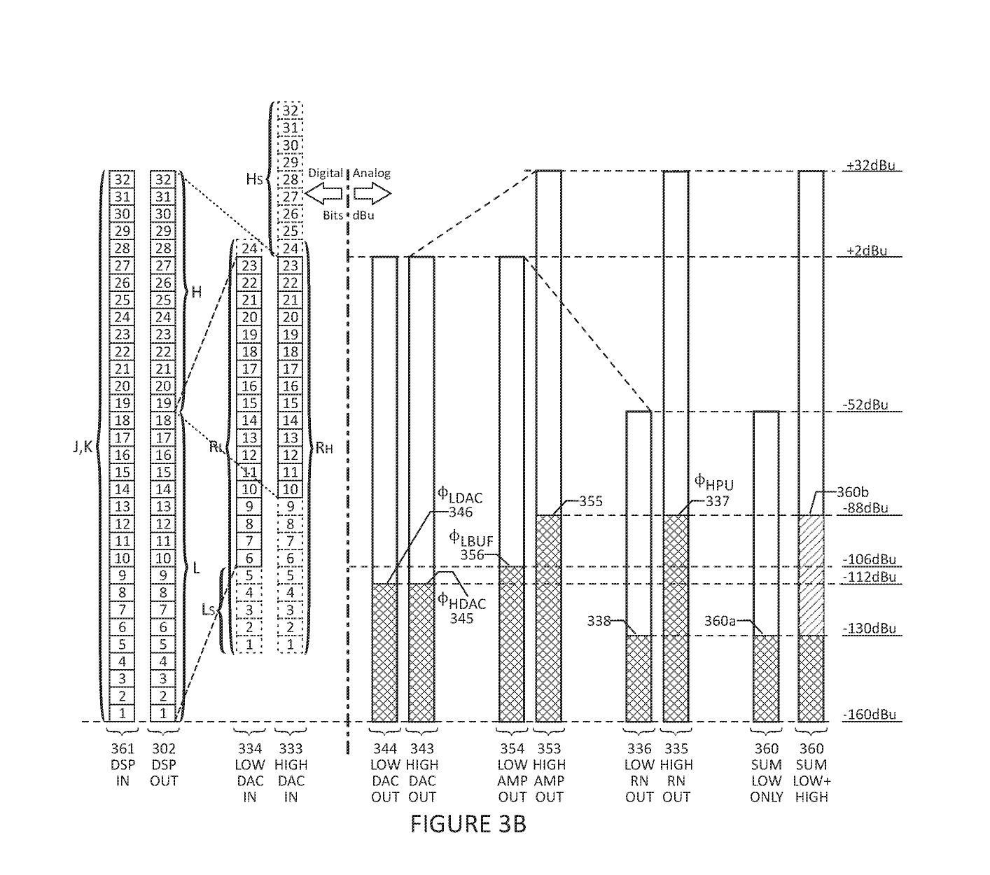

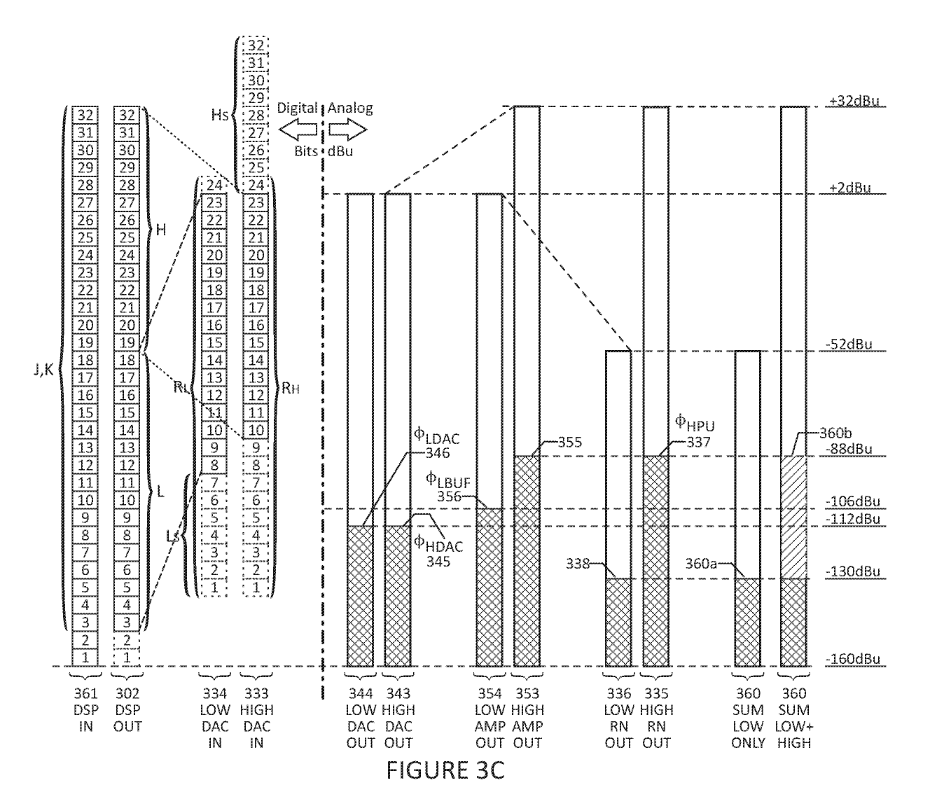

FIG. 3A provides a schematic of a two-path circuit (300) for a 32-bit signal according to a preferred embodiment of the present invention which provides increased systemic dynamic range and decreased baseline (i.e., no input signal) self-noise. As shown in the signal levels chart of FIG. 3B, the circuit of FIG. 3A divides a 32-bit input signal (361) (K=32; corresponding to a signal range of 192 dB, which for the audio circuitry according to the preferred embodiment will be assigned the range of −160 dBu to +32 dBu) into two smaller words or bit packets, a low-path-packet (334) of L=18 bits, and a high-path-packet (333) of H=14 bits. (In general, operational analog audio levels correspond to non-integer bit values of a digital signal. However, in the examples presented in the present specification integer bit values will be used to describe the invention, and since 1 bit corresponds to 6 dBu, this results in integer dB values. The use of integer values is intended for explanatory clarity only and in no way precludes the implementation of the invention using fractional values. Although the present specification does not describe the invention in terms of RMS voltages, it is noted that 0 dBu is equivalent to 0.7746 volts RMS.)

The present invention employs a digital signal processing circuit (DSP) to partition pulse code modulated (PCM) data into multiple smaller “bit packets” of contiguous or slightly overlapping data which are processed along separate data “paths” to increase dynamic range relative to what is possible with single-path DACs. Each-path (referred to as low, mid, high, etc.) is optimized for a partial dynamic range of the original digital signal, and then, according to the present invention, the signals from the multiple paths are passively summed to provide the analog output.

Conventional IC (e.g., integrated circuit) DACs are often not designed with output parameters which adequately interface with typical real-world applications, such as home audio systems, professional audio systems, or live sound systems. In contrast, the DAC of the present invention, even with its use of passive summing to provide the output signal, provides an output signal with output parameters appropriate for such real-world applications. The input to the circuit (300) of FIG. 3A may be a single digital signal source (301), or multiple digital signal sources (301) and (340), (341), etc. The digital signal source (301) or sources (301) and (340), (341), etc. are fed to a digital signal processor (DSP) (302) which divides the input signal into the high-path output (333) and the low-path output (334), and directs them (333) and (334) to a high-path DAC (303) and a low-path DAC (304), respectively. The low-path output (334) is mapped upwards by Lₛ=5 bits upon input to the low-path DAC (304), and the high-path output (333) is mapped downwards by Hₛ=9 bits upon input to the high-path DAC (303). The analog output (343) and (344) of each DAC (303) and (304) is sent to an active analog amplifier (305) and (306), respectively. Typically, integrated circuit DAC outputs are differential, but the present invention is not limited to differential signal paths and can employ differential or single-ended signal paths. The amplifiers (305) and (306) can provide a number of critical functions, including but not limited to current-to-voltage conversion (IV conversion), high and/or low frequency filtering, DC servo, current buffering/current sourcing, voltage gain, and impedance buffering. In the present invention, critical requirements of these amplifiers (305) and (306) include sufficiently low noise, sufficiently low output impedance, sufficiently high output current, and sufficiently high output voltage to properly interface with a passive analog summing node (360) which combines the low-path and high-path signals into a single analog signal capable of driving real-world external devices (309) to a sufficiently high level and wide bandwidth, while maintaining sufficiently low noise and distortion. According to an alternate preferred embodiment, the passive analog summing could be implemented using an audio signal transformer(s).

It should be noted that although the high-path output signal (335), the low-path output signal (336), and the summing node output signal (365) are assigned distinct reference numerals, the electrically connecting node (360)—which physically is simply where the conductive paths from the output of the high-path resistive element (307), the output of the low-path resistive element (308), and the input to the external device (309) meet—makes those signals electrically connected. Since those signals (335), (336) and (365) are electrically connected with no intervening circuitry, those signals (335), (336) and (365) are inherently the same at all instants. Distinct reference numerals are nevertheless used for clarity of discussion. What is referred to as the high-path output signal (335) is the portion of the output signal (365) that is generated by the high-path circuitry (303), (305), and (307), and what is referred to as the low-path output signal (336) is the portion of the output signal (365) that is generated by the low-path circuitry (304), (306), and (308).

Although the present invention can be applied to circuitry and components having a wide variety of operational parameters, described herein for the purposes of example as a first preferred embodiment is the circuit (300) of FIG. 3A which has two DACs (303) and (304) which, as shown in the signal levels chart of FIG. 3B, each can accept a 24-bit input (i.e., R_{L}=R_{H}=24), and each can produce a maximum analog level of +8 dBu with a residual broadband, unweighted audio spectrum noise floor φ_{LDAC} (346) and φ_{HDAC} (345) of −112 dBu, for a total potentially usable broadband dynamic range of 120 dB, i.e., 20 bits. Therefore, any unmapped (i.e., not processed for instance according to the present invention) digital input level (361) below −112 dBu cannot be effectively resolved at the DAC output (343) and (344) because such level is below the DACs' (303) and (304) residual broadband noise floors φ_{LDAC} (346) and φ_{HDAC} (345), respectively, of −112 dBu. Hence, each DAC (303) and (304) is effectively limited to 20-bit operation, specifically input bits 5-24 which corresponds to the range of −112 dBu to +8 dBu. (However, it should be understood that although sometimes audio program signals below a noise threshold can be psychoacoustically perceived, for purposes of example in the present specification it is assumed that the measured broadband, unweighted DAC noise floor will be the lowest usable DAC signal level.) Furthermore, amplifier output (354) exhibits a residual unity-gain audio spectrum broadband unweighted noise floor of −106 dBu, and amplifier output (353) exhibits a maximum analog level of +32 dBu with an audio spectrum broadband unweighted noise floor of −88 dBu when configured at +30 dB of gain. Any analog input level (344) below −106 dBu, or any analog input level (343) below −88 dBu, cannot be effectively resolved by amplifier devices (306) and (305), respectively, because such level is below the amplifiers' residual broadband, unweighted noise floor of −106 dBu and −88 dBu, respectively.

As shown in FIGS. 3A and 3B, the DSP (302) divides a 32-bit PCM input (361) into an L=18 bit low-path DAC input signal (334) and an H=14 bit high-path DAC input signal (333). DSP (302) input bits 1 through 18 are digitally level shift mapped upwards by Lₛ=5 bits by the DSP (302) to input bits 6 through 23 of the input (334) to the low-path DAC (304), while DSP (302) output bits 19 through 32 are digitally level shift mapped effectively downwards by Hₛ=9 bits to input bits 10 through 23 of the input (333) to the high-path DAC (303). Level shift mapping of bits is defined in the present specification as where a contiguous group of bits is mapped such that all bits are shifted by the same mapping formula, i.e., the n^{th} input bit is mapped to the (n+i)^{th} output bit, where i is the amount of level shift applied. Equivalently, a level shift mapping can be thought of as a multiplication by 2ⁱ of the signal level where i is the amount of bit level shift applied. More generally, level shift mapping is not limited to integer-wide or bit-alignment shifts within a digital register, but may result from arithmetic multiplications wherein the coefficient of multiplication may be any value within the operational range of the digital signal processing. The mapping process requires that the DSP (302) performs a level shift on the high-path signal (333) and the low-path signal (334). The input (334) to the low-path DAC (304) is shifted up by +54 dB by the DSP (302), such that an input level (361) of −160 dBu for the 32-bit DSP (302) is mapped to a level of −106 dBu in terms of the 24-bit low-path DAC input (334), i.e., according to this preferred embodiment of the present invention the lowest bit of the input (334) to the DAC (304) is mapped to just above the noise floor φ_{LDAC} (346) of the low-path DAC (304). Similarly, the input (333) to the high-path DAC (303) is effectively shifted down by −30 dB so that an input level (361) to the 32-bit DSP (302) of +32 dBu is mapped to a DAC signal level of +2 dBu at the input (333) to the 24-bit high-path DAC (303). The low-path DAC (304) receives an 18-bit signal (334) representing signal levels at the input (361) to the DSP (302) from −160 dBu to −52 dBu, i.e., a signal (334) having 108 dB of dynamic range. The 14 bits comprising the input (333) to the high-path DAC (303) represents signal levels from −52 dBu to +32 dbu, i.e., 84 dB of dynamic range.

As shown in FIG. 3B, the output (344) of low DAC (304) bit 23 has an analog level of +2 dBu and has a broadband, unweighted noise floor φ_{LDAC} (346) of −112 dBu. As also shown in FIG. 3B, the output (343) of high DAC (303) bit 23 has an analog level of +2 dBu and a broadband, unweighted noise floor φ_{HDAC} (345) of −112 dBu. As can be seen by following the successive mappings from the input (361) to the DSP (302), through the DSP (302) and the high- and low-path DACs (303) and (304), the +2 dBu signal level at the output (343) of the high-path DAC (303) represents a level of +32 dBu at the input (361) to the DSP (302), while a +2 dBu signal level at the output (344) of the low-path DAC (304) represents a level (361) of −52 dBu at the input (361) to the DSP (302).

As shown by the horizontal dashed line spanning from the top of the bar representing low-path DAC output signal (344) to the top of the bar representing low-path amplifier output signal (354) in FIG. 3B, low-path amplifier (306) is configured to provide unity gain and therefore produces an output signal (354) having a maximum level equal to that of the input (344). As can also be seen from FIG. 3B, high-path amplifier (305) is configured to provide +30 dB of gain. As mentioned earlier, the unity gain amplifier (306) has a broadband, unweighted self-noise φ_{LBUF} (356) of −106 dBu. The high-path amplifier (305) produces a gain of 30 dB and has −88 dBu of broadband, unweighted self-noise (355). Therefore, as shown in FIG. 3B, the high-path amplifier (305) amplifies an input signal (343) having a maximum level of +2 dBu by +30 dB to produce a maximum level of +32 dBu at the output (353) of the high-path amplifier (305), and the amplifier's noise floor (355) of −88 dBu is the noise floor (355) of the output signal (353).

The output (353) of the high-path amplifier (305) is fed, via series switching element (315), to a high-path passive resistive element RE2 (307) (in an alternative embodiment of the invention, not shown in FIG. 3A, the series switching element (315) may follow the resistive element (307), so that the switching element (315) is connected between (307) and (335)). The series switching element (315) is controlled by a control signal (316) provided by the DSP (302). The output (354) of the low-path amplifier (306) is fed directly to a low-path passive resistive element RE1 (308). The resistive elements (307) and (308) may perform a number of functions, including signal attenuation, noise management, impedance management and frequency filtering, when required. In the examples of FIGS. 3A and 3B, resistive elements (307) and (308) have low series resistance and provide sufficiently low output impedance at (335) and (336) for proper summing of signals (335) and (336) at node (360). According to the preferred embodiment, the resistive elements RE2 (307) and RE1 (308) both exhibit 200 ohm series resistance. Additional frequency filtering (such as high-pass and/or low-pass filtering) can be added to the high-path resistive elements (307) and (308) as may be required based on the particulars of the circuit (300) and the requirements of the external device (309).

As shown in FIG. 3B, according to the preferred embodiment, the low-path resistive element RE1 (308) produces −54 dB of attenuation, provides 200 ohms series resistance, and provides for frequency filtering as may be required by the DAC (304). According to the preferred embodiment of the present invention, the high-path resistive element RE2 (307) exhibits no attenuation, provides 200 ohms series resistance, and provides for frequency filtering as may be required by the DAC (303). Other series resistance values can be employed in the resistive elements (307) and (308). A lower resistance will provide lower overall thermal noise but with a higher potential level loss, dependent upon the destination (309) impedance. A higher resistance will cause higher overall thermal noise but with a lower potential level loss, dependent upon the destination (309) impedance.

The thermal (or Johnson-Nyquist) noise voltage Vₙ produced by a resistor of resistance R is given by

Vₙ=(4k_{B}TfR)^{1/2} (1.1)

where k_{B} is Boltzmann's Constant of 1.3806504×10⁻²³ (joule/Kelvin), T is absolute temperature in Kelvin, f is the frequency bandwidth in Hz, and R is the value of the resistance in ohms. Assuming a temperature T of 20 degrees centigrade (293.15° K), a frequency bandwidth of 20,000 Hz, and a total series resistance R of 200 ohms, the full bandwidth, unweighted noise (Vₙ) is approximately 245 nV RMS or approximately −130 dBu, as given by

dBu=20 Log₁₀(Vₙ/0.7746) with 0 dBu=0.7746 Vrms (1.2)

The summation node (360) is a simple physical electrical connection of the output signals (335) and (336) from the resistive elements (307) and (308), respectively. With sufficiently high source currents at (353) and (354), and sufficiently low series resistances of the resistive elements (307) and (308), the summation of the high-path output (335) and the low-path output (336) will properly interface with real world devices (309) while maintaining low noise and high dynamic range, as will be further described below.

When the digital input signal level (361) is below L=18 bits, the high-path switching element (315) under control of DSP (302) via control line (316) is held open (as is depicted in FIG. 3A). When this switch (315) is open, it creates an open-circuit at the input to high-path resistive element RE2 (307) resulting in effectively no thermal noise φ_{HPU} (337) from the resistive element RE2 (307) reaching the summing node (360). When high-path switching element (315) is open, the only noise which is input to the summing node (360) is the thermal noise (338) generated by the low-path resistive element RE1 (308), plus any residual noise (356) generated by prior circuit elements, such as the low-path DAC (304) and low-path amplifier (306). Given that the summed broadband noise generated by the combination of the noise φ_{LDAC} (346) from the low-path DAC (304) and the noise φ_{LBUF} (356) from the low-path amplifier (306), which is given as −106 dBu, and given that the attenuation created by low-path resistive element RE1 (308) is −54 dB, the combined noise from the low-path DAC (304) and low-path amplifier (306) is attenuated down to −160 dBu and can be neglected relative to the noise (338) of −130 dBu (roughly the thermal noise of 200 ohms series resistance) from the low-path resistive element RE1 (308).

The high-path amplifier (305) produces a gain of +30 dB, and the self-noise (355) of the high-path amplifier (305) at +30 dB gain is −88 dBu. High-path resistive element RE2 (307) provides a non-attenuated passive path which exhibits 200 ohms total series resistance (non-attenuated means, for example, that a +4 dBu signal at the input will remain a +4 dBu signal at the output when measured under no load). As the low-path output signal (336) rises and approaches a certain level, which according to the present preferred embodiment is −52 dBu, the DSP (302) sends a control signal (316) which causes high-path series switching element (315) to close (i.e., to switch to the position opposite that depicted in FIG. 3A). According to the preferred embodiment of the present invention, this switch closure occurs immediately before the DSP (302) begins to send high-path program signal to high-path DAC (303). To better anticipate the ideal point of switch (315) closure, a delay and look-ahead function could be used in the DSP (302), i.e., the input signal (361) could be slightly delayed in the DSP (302), for example on the order of a few milliseconds, while the DSP (302) determines in advance the optimal point of switch (315) closure, and activates such closure at a pre-determined optimum point.

The high-path amplifier (305) produces +30 dB of gain (which is apparent in FIG. 3B by the +30 dB increase in the height of amplifier output signal (353) relative to the DAC output signal (343)) and has −88 dBu of unweighted broadband self-noise (355). The high-path amplifier (305) is followed by resistive element RE2 (307) which has 200 ohms total series resistance and −130 dBu of unweighted broadband self-noise. Since the self-noise of the resistive element RE2 (307) is so much less than the noise (355) generated by the high-path amplifier (305), the total broadband unweighted audio path noise φ_{HPU} (337) at the output (335) of the resistive element RE2 (307) is also roughly −88 dBu. Because the high-path amplifier (305) output signal (353) is switched by high-path switching element (315) into electrical connection with the summing node (360) when the low-path (336) program level at summing node (360) approaches or exceeds −52 dBu, there exists at least a 30 dB level difference (the level difference between −88 dBu and −52 dBu) between low-path-program level (336) and high-path noise level 4 (337) when the high-path circuitry (303) and (305) is switched into electrical connection with the output node (360). The 30 dB signal-to-noise difference provides a high degree of psychoacoustic masking to the −88 dBu broadband unweighted high-path noise level (360b) added by the closure of switch (315), making the noise φ_{HPU} (337) generated by the high-path components (303), (305), (307), and (315) generally making it psychoacoustically undetectable. This is an important aspect of the present invention. (It should be noted that because of the inherent difficulty, extracting objective baseline noise measurements from active audio program is generally not attempted. Broadband noise measurements are typically taken with no program present.)

When high-path switching element (315) is open (which is the state in which it (315) is depicted in FIG. 3A), the total series resistance into the summing node (360) is 200 ohms, i.e., the inherent series resistance of low-path resistive element RE1 (308). When high-path switching element (315) is closed (i.e., the state opposite to that depicted in FIG. 3A), the parallel resistances of low-path resistive element RE1 (308) and high-path resistive element RE2 (307) produce a total resistance at output node (360) of 100 ohms, i.e., the total resistance of RE1 (308) and RE2 (307) when connected in parallel. According to the preferred embodiment of the present invention, when high-path switching element (315) is closed the DSP (302) adjusts its digital output levels (333) and (334) to compensate for any level shift of the summed output signal (365) produced by the ratio of the change in the total source resistance against the fixed destination impedance (309) as described below. The DSP calculates the amount of compensation required based on measurements it receives via ADCs (320), (325), and (330).

According to the present invention, the high-path switching element (315) is to be understood to represent any method or technique under DSP (302) control for removing the high-path output signal (335) from the summing node (360) in such a manner as to eliminate or significantly reduce the self-noise generated by the high-path components (303), (305), (307). In a differential signal path, the high-path switching element (315) could be two discrete switching elements, with one switching element per each leg of the differential signal. According to an alternate embodiment, high-path amplifier (305) may employ a selectable shut-down, mute or disable (etc.) function in which a design feature of the amplifier (305) itself allows selective (i.e., DSP (302) controlled) removal of signal and noise from the output (353) of the amplifier (305).

As shown in FIG. 3A, the signal levels at the summing node (360), high-level amplifier output (353), and low-level amplifier output (344) are monitored by analog-to-digital converters (ADCs) (320), (325) and (330) when switched into monitoring via associated series-path switching elements (321), (326) and (331), respectively. Each ADC device (320), (325) and (330) reports its analog input level to the DSP (302). In passive summing of signals (335) and (336) according to the present invention, there will generally be some amount of output level loss due to the relationships between the resistances of the high-path circuit (303), (305), and (307), low-path circuit (304), (306), and (308), and external device (309), both from the interplay of the summing build out resistances, and the source/destination resistance ratios. According to the preferred embodiment of the present invention, the ADC level reporting is used by the DSP (302) to control the level of the output signals (333) and (334) to compensate for normal passive level losses and other losses or changes in output level.

FIG. 3C shows an alternate embodiment of the present invention where not all the nominal K=32 input bits to the DSP (302) are utilized. In particular, as shown in FIG. 3C J=30 input bits are utilized. Bits 3 through 18, i.e., L=16 bits are shifted upwards by Lₛ=7 bits by the DSP (302) to provide the digital input signal (334) to the low-path DAC (304), and bits 19 through 32, i.e., H=14 bits are mapped downwards by Hₛ=9 bits by the DSP (302) to provide the digital input signal (333) to the high-path DAC (303). As indicated by the dashed lines of the first and second bits of DSP OUT (302), the first and second bits are not utilized. The number of utilized bits J=30 (which equals in this case L and H) is less than K=32 by 2. The processing of the signals in the analog portion of the signal processing, as depicted in FIG. 3C, parallels that described above for FIG. 3B.

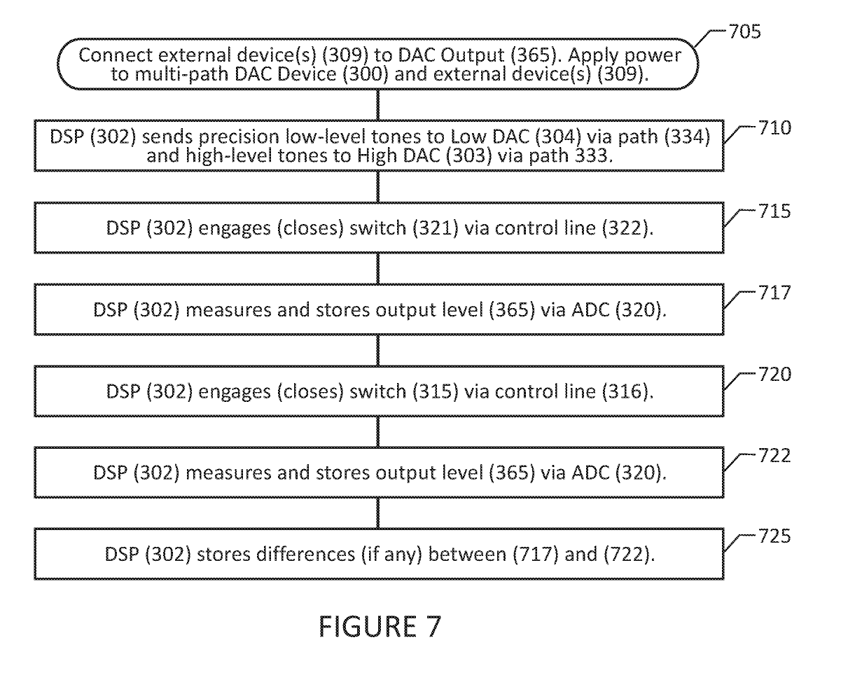

As shown in FIG. 7, immediately upon power-on (705) of the circuit (300) of FIG. 3A and external device(s) (309), the DSP (302) will send (710) a steady-state AC signal, or a sequence of steady-state signals, of precisely known amplitude through both the high-path DAC (303) and the low-path DAC (304), while holding switching element (315) open (which is the position in which it is depicted in FIG. 3). The DSP (302) will then send (715) a control signal via control line (322) to close switching element (321), and the DSP (302) will measure (717) the amplitude of the output signal (365) using ADC (320). Once the DSP (302) has determined and internally saved the precise amplitude of this first measurement, the DSP (302) will then send (720) a control signal via control line (316) to close switching element (315), thereby changing the source impedance seen at summing node (360). After switching element (315) is closed, the DSP (302) will again measure (722) the amplitude of the output signal (365) using ADC (320). The amplitude difference (if any) between the first and second measurements will be stored (725) in DSP (302) memory and used as a calibration factor to maintain linear performance in the course of impedance and resistance shifts due to the opening and closing of high-level switching element (315). If the external device (309) is changed, and especially if the destination (input) impedance of (309) is changed, this routine should be repeated to determine new calibration factors.

According to the preferred embodiment, the internal impedance of the ADCs (320), (325) and (330) is great enough that switching them (320), (325) and (330) into the circuit via switches (321), (315) and (331) causes minimal amplitude shifts of the signal they (320), (325) and (330) are measuring. According to the present invention, the internal impedances of the ADCs (320), (325) and (330) are preferably at least ten times greater, more preferably at least twenty times greater, and still more preferably at least forty times greater than the internal impedances of the components (303)/(305)/(307), and (304)/(306)/(308) in the signal paths the ADCs (320), (325) and (330) are monitoring.

Furthermore, according to the present invention, ADC (325) and ADC (330) are used to compare measured amplitudes with expected amplitudes. In particular, the DSP (302) can send control signals via control lines (327) and (328) to close high-level and low-level monitoring switches (326) and (331) thereby connecting ADCs (325) and (330) to the outputs of the high-level and low-level amplifiers (305) and (306). The difference between the measured amplitude values provided by ADCs (325) and (330) and the expected values are used by the DSP (302) to gather correction/calibration factors. The measurements will typically be taken immediately at power-on with zero input program, but can also be taken during any sufficiently long period of zero input program. Switching elements (326) and (331) are used to completely remove the ADC inputs from the low-level and high-level circuit paths when not in use, thereby fully removing any potentially detrimental electrical issues.

### A Preferred Three-Path Embodiment According to the Present Invention

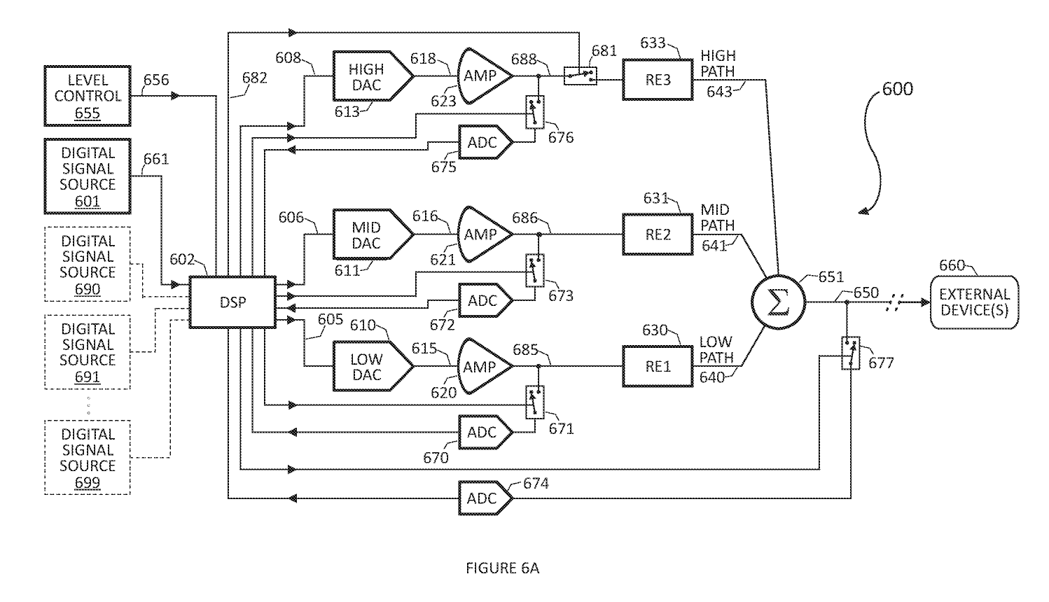

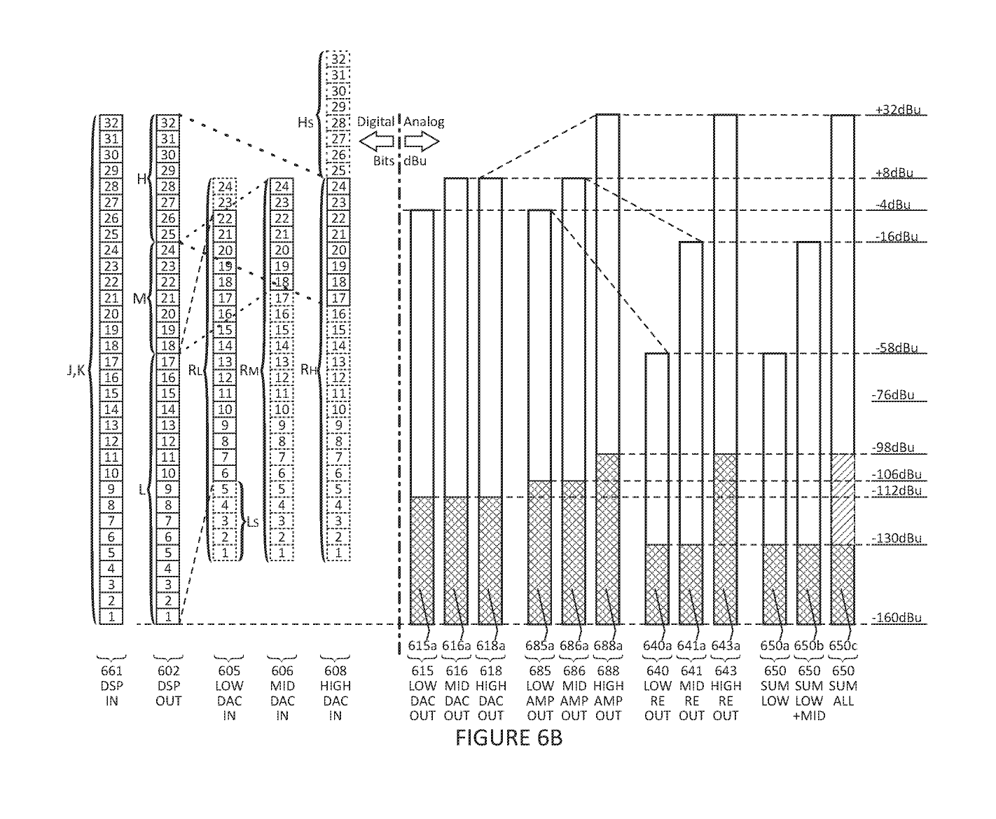

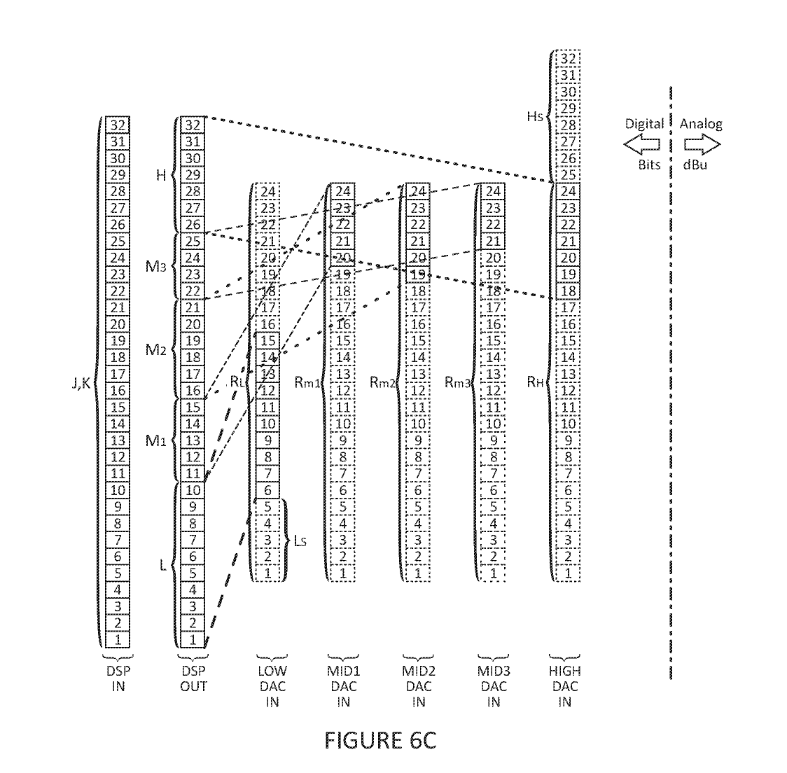

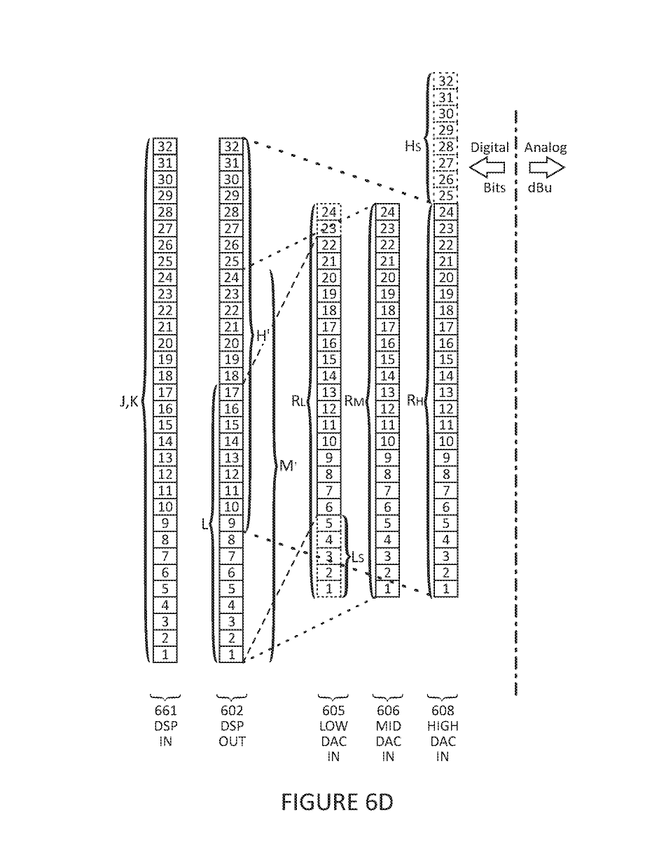

FIG. 6A provides a schematic of a three-path circuit (600) for a 32-bit signal according to a preferred embodiment of the present invention which-provides increased systemic dynamic range and decreased baseline (i.e., no input signal) self-noise. As shown in the signal levels chart of FIG. 6B, the circuit of FIG. 6A divides a 32-bit input signal (661) (corresponding to a signal range of 192 dB, which for the audio circuitry according to the preferred embodiment will be assigned the range of −160 dBu to +32 dBu) into three smaller words or bit packets, a low-path packet (605), and mid-path packet (606) and a high-path packet (608).

The input to the circuit (600) of FIG. 6A may be a single digital signal source (601), or multiple digital signal sources (601) and (690), (691), etc. The digital signal source (601) or sources (601) and (690), (691), etc. are fed to a digital signal processor (DSP) (602) which divides the input signal into a high-path output (608), a mid-path output (606) and a low-path output (605), and directs them (608), (606) and (605) to a high-path DAC (613), a mid-path DAC (611), and a low-path DAC (610), respectively. The analog output (618), (616), and (615) of each DAC (613), (611) and (610) is sent to an active analog amplifier (623), (621) and (620), respectively. Typically, integrated circuit DAC outputs are differential, but the present invention is not limited to differential signal paths and can employ differential or single-ended signal paths. The amplifiers (623), (621) and (620) can provide a number of critical functions, including but not limited to current-to-voltage conversion (IV conversion), high and/or low frequency filtering, DC servo, current buffering/current sourcing, voltage gain, and impedance buffering. In the present invention, critical requirements of these amplifiers (623), (621) and (620) include sufficiently low noise, sufficiently low output impedance, sufficiently high output current, and sufficiently high output voltage to properly interface with a passive analog summing node (651) which combines the low-path, mid-path and high-path signals into a single analog signal capable of driving typical external devices (660) to a sufficiently high level and wide bandwidth, while maintaining sufficiently low noise and distortion. Such sufficient audio specifications will be generally understood by those skilled in the art of professional audio circuit design.

Although the present invention can be applied to circuitry and components having a wide variety of operational parameters, described herein for the purposes of example as a second-preferred embodiment is the circuit (600) of FIG. 6A which has three DACs (610), (611) and (613) which, as shown in the signal levels chart of FIG. 6B, can each accept a 24-bit input (605), (606) and (608), and can each produce a maximum analog level of +8 dBu with a residual broadband, unweighted audio spectrum noise floor (615a), (616a) and (618a) of −112 dBu, giving each DAC device (610), (611) and (613) a total potentially usable broadband, unweighted dynamic range of 120 dB, i.e., 20 bits. Therefore, any unmapped digital input level (661) below −112 dBu cannot be effectively resolved at the DAC output (615), (616) or (618) because such level is below the DACs' (610), (611) and (613) residual broadband noise floor (615a), (616a) and (618a), respectively, of −112 dBu. Hence, each DAC (610), (611) and (613) is effectively limited to 20-bit operation, specifically input bits 5-24 which corresponds to the range of −112 dBu to +8 dBu. (However, it should be understood that although sometimes audio program signals below a noise threshold can be psychoacoustically perceived, for purposes of example in the present specification it is assumed that the measured broadband, unweighted DAC noise floor will be the lowest usable DAC signal level.) Furthermore, amplifiers (620) and (621) provide a maximum analog output level (685) and (686) of +32 dBu with a residual unity-gain audio spectrum broadband unweighted noise floor of −106 dBu (685a) and (686a), and amplifier (623) provides a maximum analog output level (688) of +32 dBu with a residual +24 dB gain audio spectrum broadband unweighted noise floor of −98 dBu (688a). Any analog level (615) and (616) below −106 dBu cannot be effectively resolved by amplifier devices (620) and (621), and any analog level (618) below roughly −98 dBu cannot be effectively resolved by amplifier device (623) because such levels are below the amplifiers' (620), (621) and (623) respective residual broadband, unweighted, noise floors.

As shown in FIG. 6A and FIG. 6B, the DSP (602) divides a 32-bit PCM input (661) into a low-path DAC input signal (605), a mid-path DAC input signal (606) and a high-path DAC input signal (608). Source (601) input bits (661) 1 through 17 are mapped by the DSP (602) to input bits 6 through 22 of the input (605) to the low-path DAC (610), source (601) input bits (661) 18 through 24 are mapped by the DSP (602) to input bits 18 through 24 of the input (606) to the mid-path DAC (611), while source (601) input bits (661) 25 through 32 are mapped to input bits 17 through 24 of the input (608) to the high-path DAC (613).

The mapping process requires that the DSP (602) performs a digital level shift on the high-path signal (608), the mid-path signal (606) and the low-path signal (605). The input (605) to the low-path DAC (610) is digitally level shifted by +54 dB by the DSP (602), such that an equivalent input level (661) of −160 dBu is mapped to a level of −106 dBu at the low-path DAC input (334), i.e., the lowest bit of the input (605) to the low-path DAC (610) is mapped to just above the noise floor (615a) of the DAC (610). Similarly, the input (606) to the mid-path DAC (611) is digitally level shifted by +24 dB so that an input level (661) to the DSP (602) of −16 dBu is mapped to a DAC signal level of +8 dBu at the input (606) to the mid-path DAC (611). The input (608) to the high-path DAC (613) is digitally level shifted by −24 dB so that an input level (661) to the DSP (602) of +32 dBu is mapped to a DAC signal level of +8 dBu at the input (608) to the high-path DAC (613). The low-path DAC (610) receives a 17-bit signal (605) representing signal levels at the input (661) to the DSP (602) from −160 dBu to −58 dBu, i.e., a signal (605) having 102 dB of dynamic range. The 7-bit signal comprising the input (606) to the mid-path DAC (611) represents signal levels at the input (661) to the DSP (602) from −58 dBu to −16 dBu, i.e., 42 dB of dynamic range. The 8-bit signal comprising the input (608) to the high-path DAC (613) represents signal levels at the input (661) to the DSP (602) from −16 dBu to +32 dBu, i.e., 48 dB of dynamic range.

As shown in FIG. 6B, the output (615) of low-path DAC (610) bit 22 exhibits a maximum level of −4 dBu and a broadband, unweighted noise floor (615a) of −112 dBu. As also shown in FIG. 6B, the output (616) of mid-path DAC (611) bit 24 exhibits a maximum level of +8 dBu and a broadband, unweighted noise floor (616a) of −112 dBu. As also shown in FIG. 6B, the output (618) of high-path DAC (613) bit 24 exhibits a maximum level of +8 dBu and a broadband, unweighted noise floor (618a) of −112 dBu.

FIG. 6D shows an alternate embodiment of bit mappings (relative to FIG. 6B) where the DSP (602) transfers signals (606) and (608) with the maximum numbers of bits M′=R_{M}=24 and H′=R_{H}=24 to the mid-path DAC (611) and the high-path DAC (613), respectively. FIG. 6D is a particular example which illustrates the general fact that any number of bits up to the maximum input capacity of the DACs (610), (611) and (613) (which in the current preferred embodiment is 24 bits) can be transferred from the DSP (602) to low-path DAC (610), mid-path DAC (611), and high-path DAC (613). A first dashed line from the bottom of bit 1 of DSP OUT (602) to the bottom of bit 1 of MID DAC IN (606), and a second dashed line from the top of bit 24 of DSP OUT (602) to the top of bit 24 of MID DAC IN (606), where the first dashed line is parallel to the second dashed line, shows that the bottom M′=R_{M}=24 bits of DSP OUT (602) are transferred to the mid-path DAC (611). Similarly, a third dashed line from the bottom of bit 9 of DSP OUT (602) to the bottom of bit 1 of HIGH DAC IN (608), and a fourth dashed line from the top of bit 32 of DSP OUT (602) to the top of bit 24 of HIGH DAC IN (608), where the third dashed line is parallel to the fourth dashed line, shows that the top H′=R_{H}=24 bits of DSP OUT (602) are transferred to the high-path DAC (613).

As shown by the horizontal dashed line spanning from the top of the bar representing low-path DAC output signal (615) to the top of the bar representing low-path amplifier output signal (685) in FIG. 6B, low-path amplifier (620) is configured to provide unity gain and therefore produces an output signal (685) having a maximum level (in dBu) equal to that of the input (615). As mentioned earlier, the unity gain amplifier (620) has a broadband, unweighted self-noise (685a) of −106 dBu. As can also be seen from FIG. 6B, mid-path amplifier output (686) is configured to provide unity gain and therefore produces an output signal (686) having a maximum level (in dBu) equal to that of the input (616). As mentioned earlier, the unity gain amplifier (621) has a broadband, unweighted self-noise of −106 dBu. As shown by the dashed line spanning from the top of the bar representing high-path DAC output signal (618) in FIG. 6B, to the top of the bar representing high-path amplifier output signal (688), high-path amplifier (623) is configured to provide +24 dB of gain and therefore produces an output signal (688) having an amplitude 24 dB higher than the input (618). As mentioned earlier, the high-path amplifier (623), configured with a gain of +24 dB, exhibits a broadband, unweighted self-noise (688a) of −98 dBu. Therefore, as shown in FIG. 6B, the high-path amplifier (623) amplifies an input signal (618) having a maximum level of +8 dBu by 24 dB to produce a maximum level of +32 dBu at the output (688) of the high-path amplifier (623), and the amplifier's noise floor of −98 dBu is the noise floor (688a) of the output signal (688).

The output (688) of the high-path amplifier (623) is fed, via series switching element (681), to a high-path-passive resistive element RF3 (633) (in an alternative embodiment of the invention, not shown in FIG. 6A, the series switching element (681) may follow the resistive element (633), so that the switching element (681) is connected between (633) and (643)). The series switching element (681) is controlled by a control signal (682) provided by the DSP (602). The output (686) of the mid-path amplifier (621) is fed directly to the mid-path passive resistive element RE2 (631). The output (685) of the low-path amplifier (620) is fed directly to the low-path passive resistive element RE1 (630). The resistive elements can perform a number of functions, including signal attenuation, noise management, impedance management, and frequency filtering. In the example of FIG. 6A, high-path resistive element (633) provides a low series resistance, provides sufficiently low output impedance at (643) for proper summing of signals (643), (641) and (640) at node (651), and provides for frequency filtering as may be required by DAC (613). Also in the example of FIG. 6A, the mid-path resistive element (631) provides a low series resistance, provides sufficiently low output impedance at (641) for proper summing of signals (643), (641) and (640) at node (651), and provides for frequency filtering as may be required by DAC (611). Also in the example of FIG. 6A, the low-path resistive element (630) provides a low series resistance, provides sufficiently low output impedance at (640) for proper summing of signals (643), (641) and (640) at node (651), and provides for frequency filtering as may be required by DAC (610).

As shown in FIG. 6A, and according to the preferred embodiment, the high-path resistive element RE3 (633) is a 200 ohm resistor exhibiting no series attenuation. This non-attenuated signal path is represented on FIG. 6B as a dashed horizontal line beginning at the top of the bar of the high-path amplifier output (688) and ending at the top of the bar of the high-path resistive element RE3 output (643). As shown in FIG. 6A and FIG. 6B, and according to the preferred embodiment, the mid-path resistive element RE2 (631) exhibits 200 ohms series resistance and provides −24 dB of series attenuation. This series attenuation is represented on FIG. 6B as a dashed downward sloping diagonal line beginning at the top of the bar of the mid-path amplifier output (686) and ending at the top of the bar of the mid-path resistive element RE2 output (641). As shown in FIG. 6A and FIG. 6B, and according to the preferred embodiment, the low-path resistive element RE1 (630) exhibits 200 ohms series resistance and provides −54 dB of series attenuation. This series attenuation is represented on FIG. 6B as a dashed downward sloping diagonal line beginning at the top of the bar of the low-path amplifier output (685) and ending at the top of the bar of the low-path resistive element RE1 output (640). Hence, from our earlier analysis of resistive thermal noise, and as can be seen from FIG. 6B, the noise levels (640a), (641a), (650a) and (650b) of the signals (640), (641), and (650) which follow the resistive elements RE2 (641) and RE1 (640) are all at least −130 dBu.

The summation node (651) is a simple physical electrical connection of the output signals (640), (641) and (643) from the resistive elements (630), (631) and (633), respectively. With sufficiently high source current at (685), (686) and (688), typically no less than roughly 10 mA per path, and sufficiently low series resistance of the resistive elements (630), (631) and (633), which we have given as 200 ohms per series path for our preferred embodiment, the passive summation of the high-path, mid-path, and low-path outputs (640), (641) and (643) at summing node (651) will suitably interface with typical real world external devices (660), meaning that the summed signal at (650) will maintain high level, high current, high bandwidth, low noise, and low distortion when coupled with typical external devices (660).

When the digital input signal level (661) is below 25 bits, the high-path switching element (681) under control of DSP (602) via control line (682) is held open (as is depicted in FIG. 6A). When this switch (681) is open, it creates an open-circuit at the input to high-path resistive element RE3 (633) resulting in effectively zero thermal noise from the resistive element RE3 (633) reaching the summing node (651). When high-path switching element (681) is open, the only noise which is input to the summing node (651) is the thermal noise generated by the low-path resistive elements RE1 (630) and RE2 (631), plus any residual noise generated by prior circuit elements, such as the low-path DAC (610), low-path amplifier (620), mid-path DAC (611), and mid-path amplifier (621). Given that the summed broadband noise generated by the combination of low-level DAC (610) and amplifier (620) is roughly −106 dBu (685a), and given that the attenuation created by low-path resistive element RE1 (630) is −54 dB, the noise from the low-level DAC (610) and amplifier (620) is attenuated by RE1 (630) down to −160 dBu and can be neglected relative to the thermal noise of −130 dBu (640a) generated from the low-path resistive element RE1 (630). Given that the summed broadband noise generated by the combination of the mid-level DAC (611) and mid-level amplifier (621) is roughly −106 dBu (686a), and given that the attenuation created by mid-path resistive element RE2 (631) is −24 dB, the sum of all broadband noise from the mid-level DAC (611), mid-level amplifier (621), and mid-path resistive element RE2 (631) is roughly −130 dBu (641a). When the low-path output (640) and the mid-path output (641) are combined at the summing node (651), the 200 ohms series resistance of the low-path resistive element RE1 (630) combines in parallel with the 200 ohms series resistance of the mid-path resistive element RE2 (631), creating a total series resistance of 100 ohms, which can further reduce the total thermal noise (650b) as measured at the summing node (651).

The high-path amplifier (623) produces a gain of +24 dB, and the self-noise (688a) of the high-path amplifier (623) at +24 dB gain is −98 dBu. High-path resistive element RE3 (633) is a non-attenuated passive path which exhibits 200 ohms series resistance. As the mid-path output signal (641) rises to/approaches a certain level, which according to the present preferred embodiment is −16 dBu, the DSP (602) sends a control signal (682) which causes high-path series switching element (681) to close (i.e., to switch to the position opposite that depicted in FIG. 6A). According to the preferred embodiment of the present invention, this switch closure occurs immediately before the DSP (602) begins to send high-path-program signal (608) to high-path DAC (613).

The high-path amplifier (623) produces +24 dB of gain (which is apparent in FIG. 6B by the 24 dB increase in the height of amplifier output signal (688) relative to the DAC output signal (618)) and has −98 dBu of unweighted broadband self-noise (688a). The high-path amplifier (623) is followed by resistive element RF3 (633) which has 200 ohms total series resistance and −130 dBu of unweighted broadband self-noise. Since the self-noise of the resistive element RF3 (633) is so much less than the noise generated by the high-path amplifier (623) and high-path DAC (613), the total broadband unweighted audio path noise (643a) at the output (643) of the resistive element RE3 (633) is roughly −98 dBu. Because the high-path amplifier (623) output signal (688) is switched by high-path switching element (681) into electrical connection with the summing node (651) when the mid-path program level (641) at summing node (651) is at or near −16 dBu, there exists a roughly 80 dB level difference (the level difference between −98 dBu and −16 dBu) between mid-path-program level (641) and high-path noise level (650c) when the high-path (643) is switched into electrical connection with the output summing node (651). The roughly 80 dB signal-to-noise difference provides a very high degree of psychoacoustic masking to the −98 dBu broadband unweighted high-path noise level added by the closure of switch (681), making the total noise (650c) generated by the high-path components (613), (623), (681) and (633) generally psychoacoustically undetectable. (It should also be noted that, because of the inherent difficulty, extracting noise measurements from active audio program is generally not attempted. Broadband noise measurements are typically taken with no signal present.)

When high-path switching element (681) is open (which is the state in which it (681) is depicted in FIG. 6A), the total series resistance into the summing node (651) is 100 ohms, i.e., the total series resistance of low-path and mid-path resistive element RE1 (630) and RE2 (631) in parallel. When high-path switching element (681) is closed (i.e., the state opposite to that depicted in FIG. 6A), the parallel resistances of low-path resistive element RE1 (630), mid-path resistive element RE2 (631) and high-path resistive element RE3 (633) produce a total series resistance at output node (651) of 66.67 ohms, i.e., the total resistance of RE1 (630), RE2 (631) and RE3 (633) when connected in parallel. At the moment in which high-path switching element (681) is closed, according to the preferred embodiment of the present invention, the DSP (602) adjusts its high-path digital output levels (605), (606) and (608) as required to compensate for any level shift of the output signal (650) produced by the change in the total circuit resistance. The DSP (602) calculates the amount of compensation required based on prior measurements it receives via ADCs (670), (672), (674) and (675), as described elsewhere.

According to the present invention, the high-path switching element (681) is to be understood to represent any method or technique under DSP (602) control for removing the high-path output signal (643) from the summing node (651) in such a manner as to eliminate or significantly reduce the self-noise generated by the high-path components (613), (623) and (633).

In a differential signal path, the high-path switching element (681) could be two discrete switching elements, with one switching element per each leg of the differential signal. (According to an alternate embodiment, more than one DAC path may employ a series-switching element used for the purpose of removing path noise from the summing node.) According to an alternate embodiment, high-path amplifier (623) may employ a selectable shut-down, mute or disable (etc.) function in which a design feature of the amplifier (623) itself allows selective (i.e., DSP (602) controlled) removal of signal and noise from the output (643) of the amplifier (623). In the preferred embodiment, a reed relay is used for switching element (681) due to its fast switching speed, electrically and physically quiet operation, and complete removal of the high-path noise generation devices (613), (623) and (633) from the output summing node (651).

As shown in FIG. 6A, the signal levels, at the output of the summing node (651), high-path amplifier (688), mid-path amplifier (686), and low-path amplifier (685) are monitored by analog-to-digital converters (ADCs) (674), (675), (672) and (670), respectively, when switched into monitoring via associated series-path switching elements (677), (676), (673) and (671), respectively. Each ADC device (674), (675), (672) and (670) reports its analog input level to the DSP (602).

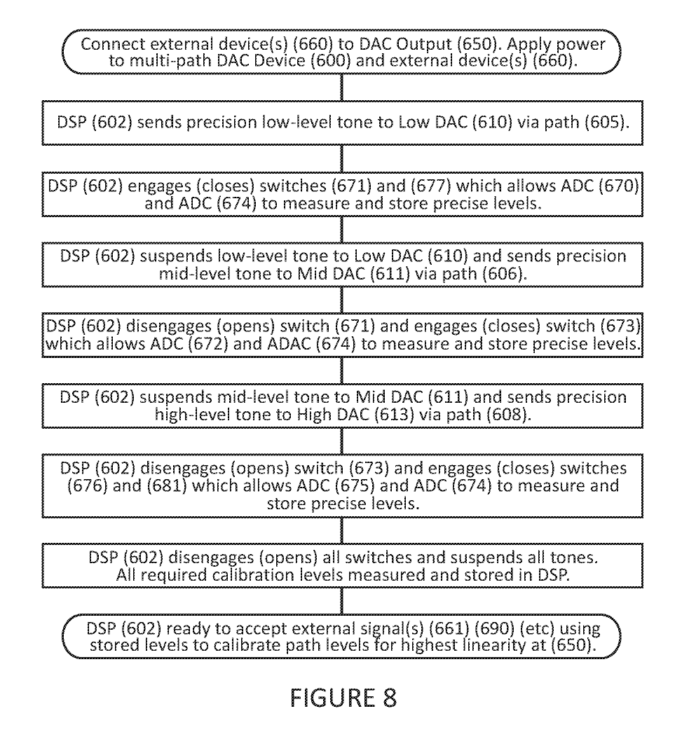

One preferred embodiment of ADC monitoring for DSP calibration is given in the flow chart of FIG. 8. According to the preferred embodiment of the present invention, ADC level reporting is used by the DSP (602) to adapt to circuit variations by calibrating the level of the output signals (688), (686), (685) and (650). If the external device (660) is changed, and especially if the destination (input) impedance of (660) is changed, the calibration routine described below and shown in FIG. 8 should be repeated to determine new calibration factors. According to the preferred embodiment, the internal impedance of the ADCs (674), (675), (672) and (670) is great enough that switching them (674), (675), (672) and (670) into the circuit via switching elements (677), (676), (673) and (671) causes minimal amplitude shifts of the signal they (674), (675), (672) and (670) are measuring. According to the present invention, the internal impedances of the ADCs (674), (675), (672) and (670) are preferably at least ten times greater, more preferably at least twenty times greater, and still more preferably at least forty times greater than the impedance of the circuit point the ADCs (674), (675), (672) and (670) are monitoring.

Furthermore, according to the present invention, ADC (674), (675), (672) and (670) are used to compare measured amplitudes with expected amplitudes. In particular, the DSP (602) can close any desired combination of switching elements (677), (676), (673) and (671), thereby connecting ADCs (674), (675), (672) and/or (670) to the outputs (688), (686) and (685) of the high-, mid- and low-level amplifiers (623), (621) and (620), and the summed output node (651). The difference between the measured amplitude values provided by ADCs (674), (675), (672) and/or (670) and the expected values in DSP (602) memory are used by the DSP (602) for correction/calibration factors. The calibration measurements will typically be taken at power-on with zero input program (661), but can also be taken during any sufficiently long period of zero input program (661). Switching elements (677), (676), (673) and (671) are used to completely remove the ADC inputs from their respective circuit paths when not in use, thereby fully removing any potentially detrimental electrical issues.

As shown in FIG. 6A, the circuit (600) of the present invention is not limited to a single digital signal source (601), i.e., the circuit (600) may be utilized for the D-A conversion of a plurality of previously conditioned multi-path signals (i.e., any contiguous signal that has been pre-conditioned (split) into two or more discrete paths for the purpose of improved dynamic range, such as given by the example of patent US20140328501.) Additional digital signal input sources (690), (691) . . . (699) are represented here in a multi-input parallel topology for clarity, but such multi-path sources can also be configured in a single input serial topology, or hybrid series-parallel topology, or any other appropriate method or topology of digital data transfer, transmission, and/or input.

A method of level control will now be described which takes advantage of the novel architecture of the present invention, wherein the levels of the analog outputs (685), (686), and (688) of the DAC devices (620), (621) and (623) are shifted by dynamically altering the DSP multi-path bit shift mapping characteristics.

As described above in reference to FIG. 6A, a digital signal (661) is mapped into multiple DAC devices (610), (611) and (613) by DSP (602). The mapping is done in a manner which achieves a fixed (non-adjustable) analog level range at the output (650) with respect to the input (661). However, according to this alternate embodiment the level of the analog output (650) can be varied, either higher or lower, by adjusting the mapped location of input bits (661) via a level adjustment control (655) connected to DSP (602) via signal path (656), as is shown in FIG. 6A. The level adjustment control (655) can be any manner of input control or control device to the DSP which provides a signal (656) to the DSP (602) which instructs the DSP (602) to carry out a resultant level adjustment. Some examples of such a level control (655) or control device (655) include, but are not limited to, gray-coded rotary encoder control, quadrature rotary encoder control, up-down control via switches, or any other means well-known to those skilled in the art of digital control.

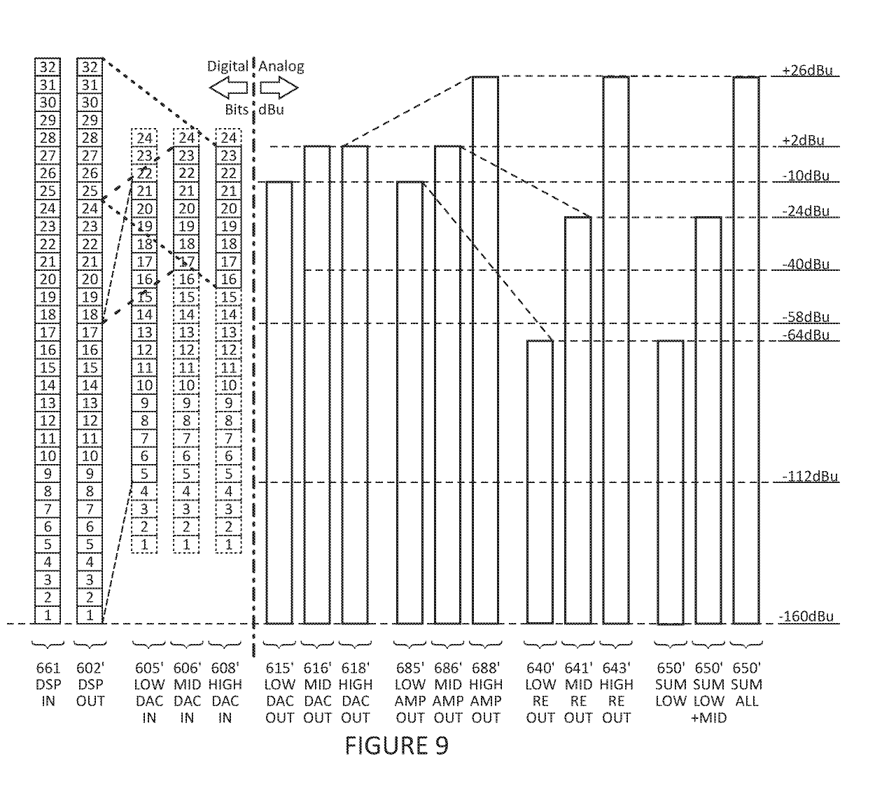

As shown in FIG. 6B, the 32 bit digital input signal (661) corresponds to an analog level range of −160 dBu to +32 dBu resulting in a usable output (650) level range of −130 dBu to +32 dBu. The cross-hatching below −130 dBu indicates that range is not usable because of noise. In comparison, FIG. 9 shows an example where the maximum level of the output (650′) is reduced by −6 dB relative to the digital input signal (661). (Shifted levels relative to those of FIG. 6B are noted by primed reference numerals. For clarity of depiction, the noise levels shown in FIG. 6B are not depicted in FIG. 9 since their characteristics are adequately described in FIG. 6B.) This −6 dB reduction in output range is achieved by a downward level shift by the DSP (602) by 1 bit at each input (605′), (606′), and (608′) to the DACs (610), (611) and (613). More specifically, as shown in FIG. 9, to achieve a level reduction of −6 dB at the output (650′) relative to the output level (650) achieved in FIG. 6B, the source (601) input bits (661) 1 through 17 are mapped by the DSP (602) to input bits 5 through 21 of the input (605′) to the low-path DAC (610), source (601) input bits (661) 18 through 24 are mapped by the DSP (602) to input bits 17 through 23 of the input (606′) to the mid-path DAC (611), and source (601) input bits (661) 25 through 32 are mapped by the DSP (602′) to input bits 16 through 23 of the input (608′) to the high-path DAC (613).

Therefore, as shown in FIG. 9, to achieve the −6 dB output (650′) level reduction relative to the output level (650) achieved in FIG. 6B, the DSP (602) performs a digital level shift such that the input (605′) to the low-path DAC (610) is shifted up by 4 bits by the DSP (602) so that bit 1 of input signal (661), which corresponds to an analog level of −160 dBu in the 32-bit DSP (602), is mapped to bit 5 of the low-path DAC (610), which corresponds to a level of −112 dBu of the 24-bit low-path DAC output (615′). The input (606′) to the mid-path DAC (611) is shifted down by 1 bit by the DSP (602′) so that bit 18 of input signal (661), which corresponds to an analog level of −58 dBu in the 32-bit DSP (602), is mapped to bit 17 of the mid-path DAC (611), which corresponds to an analog level of −40 dBu at the output (616′) of the 24-bit mid-path DAC (611). The input (608′) to the high-path DAC (613) is shifted down by 9 bits by the DSP (602′) so that bit 32 of input signal (661), which corresponds to an analog level of +32 dBu in the 32-bit DSP (602), is mapped to bit 23 of the high-path DAC (613), which corresponds to an analog level of +2 dBu at the output (618′) of the high-path DAC (613).

Therefore, when the low-path bits (605′), mid-path bits (606′), and high-path bits (608′) are shifted in the manner described above and shown in FIG. 9, the analog level of DAC outputs (615′), (616′), and (618′) are −6 dB lower relative to the DAC output levels (615), (616), and (618) described above in reference to FIG. 6B. Furthermore, when the low-path bits (605′), mid-path bits (606′), and high-path bits (608′) are all shifted in a manner described above and shown in FIG. 9, the output levels (685′), (686′), and (688′) of amplifiers (620), (621), and (623) are −6 dB lower than the amplifier output levels (685), (686), and (688) described above in reference to FIG. 6B, respectively. Furthermore, when the low-path bits (605′), mid-path bits (606′), and high-path bits (608′) are shifted in the manner described above and shown in FIG. 9, the output levels (640′), (641′), and (643′) of resistive elements (630), (631), and (633) are is −6 dB lower than the resistive element output levels (640), (641), and (643) described above in reference to FIG. 6B. Hence, the low-path, mid-path, and high-path output signals (640′), (641′), and (643′) shown in FIG. 9 are at all times −6 dB lower than the low-path, mid-path, and high-path output signals (640), (641), and (643) shown in FIG. 6B, and FIG. 9 describes an embodiment of the invention where a −6 dB level shift at output (650′) is achieved relative to the output level (650) described above in reference to FIG. 6B. Therefore, a downward level shift at the analog output (650) can be realized via appropriate digital level shifting implemented by the DSP (602). Similarly, an upward relative level shift at analog output (650) can also be realized via appropriate digital level shifting implemented by the DSP (602).

For clarity, the level shifting described above is implemented by integer-stepped bit shifts, resulting in 6 dB increments in shifts of level. But more generally, DSP-implemented level shift adjustments can be realized in steps smaller than 6 dB by manipulations of bit values for the non-most-significant bits. Level shift mapping, as described above, is not limited to integer-wide or bit-alignment shifts within a digital register, but may result from arithmetic multiplications wherein the coefficient of multiplication may be any value within the operational range of the digital signal processing. For a change in level to be psychoacoustically perceived as linear (i.e., non-stepped) audio level changes of no greater than roughly 0.1 dB per increment are required, i.e., increments at or below the “just noticeable difference” in level shifts (see Introduction to the Physics and Psychophysics of Music, Juan Roederer, Springer Verlag, 1978, p 81, which is incorporated herein by reference).

According to an alternate embodiment of the present invention, rather than the DSP (602) implementing the level controls, there is a means for level control associated with each DAC. Each level control may be implemented as an analog potentiometer, adjustable resistor, or a digitally-controlled analog leveling device, or a digital gain function in the DSP (602), or a gain control in the DAC devices (610), (611) and (613) themselves.

It should be understood that the system of the present invention may also be applied to more than three paths. For instance, FIG. 6C shows an exemplary division of a K=32 bit input signal into a L=10 bit low-path signal taken from bits 1 through 10 of DSP IN, a first M₁=5 bit middle-path signal taken from bits 11 through 15 of DSP IN, a second M₂=6 bit middle-path signal taken from bits 16 through 21 of DSP IN, a third M₃=4 bit middle-path signal taken from bits 22 through 25 of DSP IN, and a H=7 bit high-path signal taken from bits 26 through 32 of DSP IN. The DSP digitally level shifts the L=10 bit low-path signal upwards by 5 bits to provide LOW DAC IN. It should be noted that bits 16 through 24 of the R_{L}=24 low-path DAC are not utilized. As indicated by the dashed boxes of bits 1 through 19 of MID1 DAC IN, the DSP shifts the M₁=5 bit first middle-path signal upwards 9 bits. As indicated by the dashed boxes of bits 1 through 18 of MID2 DAC IN, the DSP shifts the M₂=6 bit second middle-path signal upwards by 3 bits. And as indicated by the dashed boxes of bits 1 through 20 of MID3 DAC IN, the DSP shifts the M₃=4 bit third middle-path signal downwards by 1 bit. As indicated by the dashed boxes of bits 1 through 17 and 25 through 32 of HIGH DAC IN, the DSP shifts the H=7 bit high-path signal downwards by Hₛ=8 bits. In this example, LOW DAC IN, MID1 DAC IN, MID2 DAC IN, MID3 DAC IN, MID4 DAC IN and HIGH DAC IN have input ranges of R_{L}=R_{M1}=R_{M2}=R_{M3}=R_{H}=24 bits.

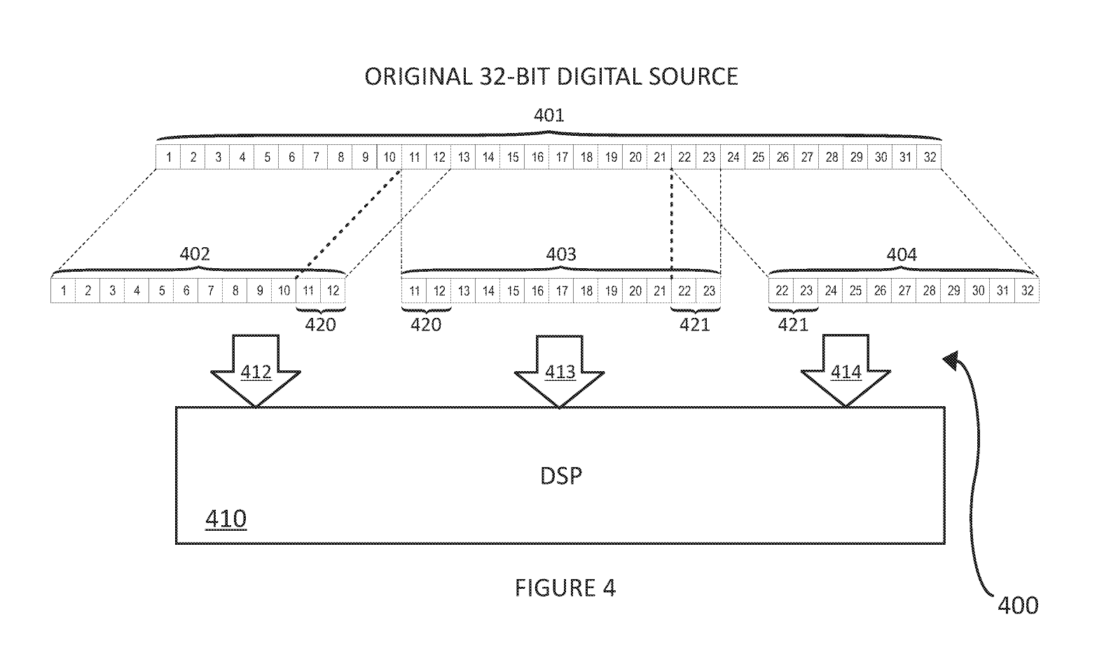

As depicted in FIG. 4, according to an alternate embodiment of the present invention rather than having the DSP (410) divide an incoming digital signal into bit paths (111) and (112), or (203), (204) and (205), or (333) and (334) as shown in FIGS. 1A, 1B, 2A, 2B and 3A, the digital signal processor (DSP) (410) may have multiple digital inputs (412), (413) and (414) which receive digital signals (402), (403), and (404), respectively, which represent portions of an original digital signal (401). Although a 32-bit digital input signal (401) is shown in FIG. 4, it should be noted that the input signal (401) may be comprised of any number of bits. The original input signal (401) is divided into three smaller partial input signals (402), (403) and (404) that each feed separate DSP (410) inputs (412), (413) and (414). The partial signals (402), (403) and (404) may have some overlap of data between paths, such as is shown FIG. 4 where bits 11-12 (420) are shared by low-level and mid-level signals (402) and (403), and bits 22-23 (421) are shared by mid-level and high-level signals (403) and (404). Alternatively, the partial-path signals (402), (403) and (404) may be contiguous with no bit overlap. According to another alternative embodiment, any number of partial-path sources could be packaged into a single serial data stream, or any other manner of digital transmission or input. In one alternative embodiment, the processing would then be as shown in FIG. 3A, where the DSP (in this case (401) rather than (302)) would then align the multi-path input data (402), (403) and (404) into two output paths feeding high-level DAC (303) and low-level DAC (304). The invention provides for any multiple of multi-path input signals to feed any number of multi-path DACs, divided into any number of bits, or sub-bit coefficient multiplier, per path.

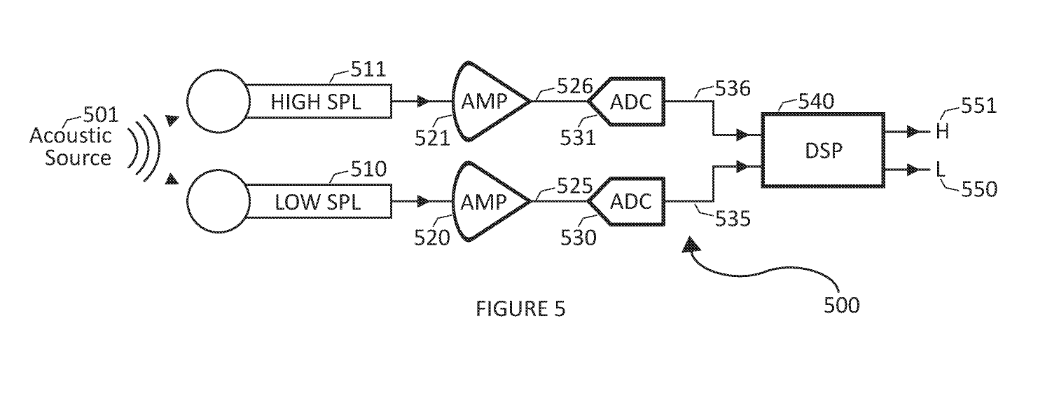

In another alternate embodiment (500) shown in FIG. 5, two audio microphones (510) and (511) are utilized. The two microphones (510) and (511) are exposed to a wide dynamic range acoustic source (501). Microphone (510) is optimized for performance with relatively low sound-pressure level (SPL) acoustic signals. Microphone (511) is optimized for performance with relatively high SPL acoustic signals. Each microphone (510) and (511) feeds a conditioning amplifier (520) and (521), respectively, with each conditioning amplifier (520) and (521) providing suitable gain, input and output impedance, and other preferred-performance characteristics as familiar to one skilled in the art of microphone termination, for instance according to the means and methods described in www.thatcorp.com/datashts/AES129_Designing_Mic_Preamps.pdf, which is incorporated herein by reference. The high-path and low-path outputs (526) and (525) from the conditioning amplifiers (521) and (520), being suitably conditioned, are then fed to analog-to-digital converters (ADCs) (531) and (530), respectively. The output of each ADC (536) and (535) then feeds the inputs of a suitable DSP (540). The system (500) of FIG. 5 may be applied to the system (300) of FIG. 3A, in which case the outputs (536) and (535) of the ADCs (531) and (530) would be the digital signal sources (301) and (340), and the digital outputs (551) and (550) would be the inputs (333) and (334) to the high-path DAC (303) and the low-path DAC (304), respectively.

Of course, FIG. 4 and FIG. 5 show just two examples (400) and (500) among myriad possible applications of the present invention for feeding multiple DACs a plurality of digital signals that represent a single program (as opposed to feeding a single original signal to DSP that then feeds multiple multi-path DACs). Any number of microphones, or any other plurality of multi-path-program signals, could for instance be used.

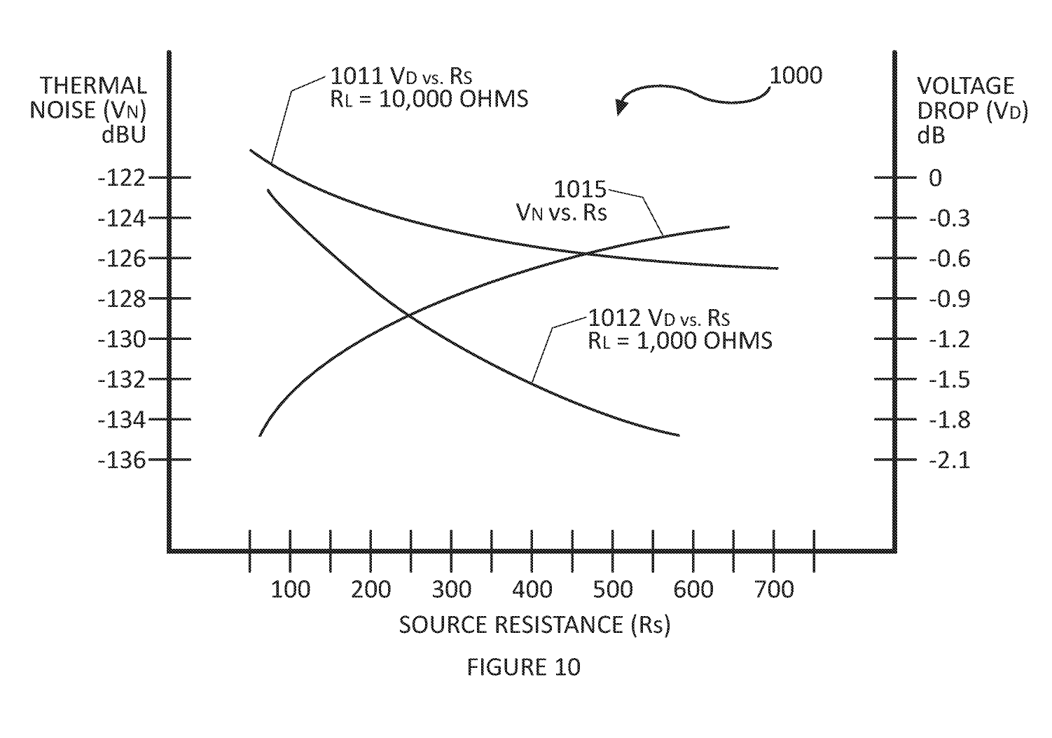

As per equations (1.1) and (1.2), thermal noise V_{N} rises with circuit source resistance Rₛ as is shown in FIG. 10 by curve (1015). Therefore, the resistances of the resistive elements (307) and (308) and (630), (631) and (633) must not be too large or else signal-to-noise will be compromised. As is also shown in FIG. 10, as the source resistance Rₛ increases, the voltage drop VD across the output increases (1011) and (1012), where the amount of voltage drop VD is dependent also on the load R_{L} of the external device(s) (309) and (660). Therefore, it is advantageous for the resistive elements (307), (308), (630), (631) and (633) to have a low level of resistance providing low systemic signal-to-noise and voltage drop. Therefore according to the present invention, it is preferred criteria for each resistive element to have a resistance of between 10 and 1,000 ohms, and more preferably a resistance between 30 and 300 ohms.

Thus, it will be seen that the improvements presented herein are consistent with the objects of the invention described above. While the above description contains many specificities, these should not be construed as limitations on the scope of the invention, but rather as exemplifications of preferred embodiments thereof. Many other variations are within the scope of the present invention. For instance: the invention is not limited to 32-bit input signal—an input signal of any bit length signal may be used; the allocation of bits between paths may or may not include overlapping bits or fractional bit levels (i.e., less than one full bit) thereof; the switching in and out of mid- and high-path circuitry may be rapid or involve fade-ins and fade-outs, or dithering; the digital signal processor may be any manner of digital processor (such as FPGA, etc.) that has adequate speed, bandwidth, input/output capabilities, and programmable features to perform the necessary processing; although 200 ohm resistive elements are taught, the invention can be designed with any resistances appropriate and suitable to low noise, high performance passive summing; the resistive elements may generate values of attenuation (or no attenuation) other than the particular values taught above—the invention can function successfully over a wide range of attenuation values when suitably designed in consort with other parameters of the circuitry; the invention is not limited to 2-path and 3-path topologies, and any number of paths can be employed according to the present invention; the high-path (or higher paths) series switching element(s) can be any means for removing the high-path(s) output signal(s) from electrical connection with the summing node in such a manner as to eliminate or significantly reduce the self-noise generated by the high-path(s) components—possible means could include, but are not limited to, (1) selectively shutting down the path amplifier via power supply, internal shutdown or disable pin, or other methods, (2) grounding the high-path(s) through a suitable grounding path resistance(s), (3) using a low noise CMOS or FET or related active switching device (although it should be noted that 1-ET and CMOS devices may have inherently higher self-noise than what is taught above); methods of timing the high-path(s) switching may involve digitally controlled signal delay and look-ahead techniques; although specific examples of path switching threshold levels are described herein, the invention is not limited to these specific switching levels and may employ other switching threshold levels and/or other switch timing dynamics (e.g., a switch may be held closed for some period of time even though the output signal level may drop below the threshold point where the switch was described above as changing state from opened to closed); although specific analog-to-digital converter calibration procedures are described herein, the invention is not limited to such calibration criteria, and may follow other calibration procedures which may be optimized for various design variations; digitally-controlled (i.e., DSP-controlled) resistances may be used if required to meet compensation goals; high-path(s) resistive elements can be implemented up-stream from the switching elements to improve noise and/or switching performance; although the circuits are diagramed and described in terms of discrete items (e.g, amplifiers, digital-to-analog converters, resistive elements, switching elements, etc.), multiple discrete elements may be integrated into a single integrated circuit or other integrated or modular system; although amplifiers with particular characteristics are described herein (e.g., a maximum output of +32 dBu and a unity gain noise floor of −106 dBu), the invention is not limited to amplifiers with these characteristics and may employ any type of low noise, single-ended or differential, audio-grade amplifiers; the high-path(s) switching element(s) may be positioned between the resistive element and the output node; although digital-to-analog converters (DACs) with particular characteristics are described herein (e.g., 24 bit input, −112 dBu noise, 120 dB usable dynamic range, etc.), the invention is not limited to DACs with these characteristics and may employ any type of audio-grade DAC; although unipolar or unsigned DAC topology is used herein for explanatory clarity, the invention is not limited to unipolar or unsigned style DACs and may employ any topology of DAC, including but not limited to signed, bipolar or twos-compliment DAC topologies; although an exemplary systemic level shift of −6 dB is described herein, the invention is not limited to any specific systemic level shift value, i.e., any value of level shift within the programmable range of the DSP can be utilized; while level shift and/or mapping examples are shown and described in terms of integer numbers of bits (which corresponds to 6 dB analog domain level shifts) for clarity of explanation, the present invention may utilize level shifting corresponding to non-integer numbers of bits, and such level shifts may be implemented by multiplication with any convenient or relevant coefficient(s), or through computation and/or programming of exponent register values; one or more analog-to-digital converters may be switched between paths utilizing associated relays so that, for instance, a single analog-to-digital converter may be utilized in multiple paths; while the preferred embodiments are described in terms of discrete functional elements (e.g., DSP, DAC, amplifier, resistive element, etc.), functional elements may be integrated into a common device—for instance, an amplifier function may be integrated into a DAC device so that the DAC device may possess an output with sufficiently low output impedance, sufficiently high output current, sufficiently high output gain capability, sufficient frequency filtering characteristic, etc., i.e., the integrated DAC device performs functions which might otherwise be in the domain of an external amplifier device—or for instance, a DAC device may be integrated into a DSP device, or a resistive element possessing proper output resistance and/or attenuation characteristics, etc., may be integrated into the integrated DAC and DSP device, etc.; while certain descriptions and claims describe digital level shifting or level mapping or bit mapping using directional language such as “upward” or “downward,” such language is used for explanatory clarity and may or may not represent a scalar upward or downward “direction”; etc. Accordingly, it is intended that the scope of the invention be determined not by the embodiments illustrated or the physical analyses motivating the illustrated embodiments, but rather by the appended claims and their legal equivalents.

What is claimed is:

1. An apparatus for conversion of an input digital signal to an output analog signal having a maximum output level, said input digital signal being nominally a signal of K bits, comprising:
a bit grouping providing system which provides said input digital signal as a low-path digital signal of L bits and a high-path digital signal of H bits, where L+H is greater than or equal to J, and J is a number of bits of said input digital signal utilized by said bit divider where J is less than or equal to K,
a low-path digital-to-analog converter for digital inputs of R_{L} bits or less, said low-path digital signal being bit shift mapped to an input of said low-path digital-to-analog converter where L is less than or equal to R_{L}, wherein the L bits of the low-path digital signal are level shift mapped upwards by Lₛ bits where L+Lₛ≦R_{L}, said low-path digital-to-analog converter producing a low-path digital-to-analog converter output signal,
a high-path digital-to-analog converter for digital inputs of R_{H} bits, said high-path digital signal being level shift mapped downwards to an input of said high-path digital-to-analog converter by a bit shift of Hₛ bits such that (K−Hₛ)≦R_{H} and (K−H−Hₛ)≧0, said high-path digital-to-analog converter producing a high-path digital-to-analog converter output signal,
a low-path attenuator which attenuates said low-path digital-to-analog converter output signal to produce an attenuated low-path analog signal,
a high-path amplifier which amplifies said high-path digital-to-analog converter output signal to produce an amplified high-path signal having a maximum level equal to said maximum output level, and
a passive summing node which, if a signal level characteristic of said input digital signal exceeds a threshold level, sums a penultimate low-path signal derived from said attenuated low-path analog signal and a penultimate high-path signal derived from said amplified high-path signal to produce said output analog signal and, if said signal level characteristic of said input digital signal does not exceed said threshold level, utilizes a means to reduce access of noise from said high-path amplifier to said passive summing node.

2. The apparatus of claim 1 wherein said bit grouping providing system is a bit divider which divides said input digital signal into said low-path digital signal of L bits and said high-path digital signal of H bits.

3. The apparatus of claim 2 wherein (L+H−J) is the number of bits of overlap between said low-path digital signal and said high-path digital signal.

4. The apparatus of claim 1 further including a high-path resistive element between said high-path amplifier and said passive summing node, the thermal noise of said high-path resistive element being less than noise in said amplified high-path signal.

5. The apparatus of claim 1 wherein said low-path attenuator attenuates said low-path digital-to-analog converter output signal by an attenuation factor such that said attenuated low-path analog signal has a maximum level corresponding to the highest bit of said low-path digital signal.

6. The apparatus of claim 1 wherein said low-path digital-to-analog converter has a DAC-output noise level of φ_{LDAC} dBu which corresponds to non-integer bit N_{LDAC} of the input to said low-path digital-to-analog converter, and wherein Lₛ is greater than or equal to N_{LDAC}.

7. The apparatus of claim 6 wherein said high-path digital-to-analog converter has a DAC-output noise level of φ_{HDAC} dBu which corresponds to non-integer bit N_{HDAc} of the input to said high-path digital-to-analog converter, and wherein (J−(H+Hₛ))≧N_{LDAC}.

8. The apparatus of claim 1 wherein said threshold level is substantially greater than a noise level φ_{HPU} dBu of said penultimate high-path signal.

9. The apparatus of claim 1 wherein J is an integer difference in bits between a maximum level of said input digital signal and a noise floor of said input digital signal.

10. The apparatus of claim 1 wherein said low-path digital-to-analog converter output signal is passed through a low-path buffer.

11. The apparatus of claim 10 wherein said low-path buffer is a unity gain buffer amplifier.

12. The apparatus of claim 10 wherein said low-path buffer has a low-path buffer noise level of φ_{LBUF} dBu corresponding to a non-integer bit N_{LBUF} of said input digital signal, and wherein Lₛ is greater than or equal to N_{LBUF}.

13. The apparatus of claim 10 wherein a buffer output signal which is output from said low-path buffer passes through a low-path resistive element in route to said passive summing node.

14. The apparatus of claim 13 wherein said low-path resistive element has a resistance between 50 and 5000 ohms.

15. The apparatus of claim 13 wherein said low-path resistive element has a resistance between 100 and 350 ohms.

16. The apparatus of claim 1 wherein said amplified high-path signal passes through a high-path resistive element in route to said passive summing node.

17. The apparatus of claim 16 wherein said high-path resistive element has a resistance between 50 and 5000 ohms.

18. The apparatus of claim 16 wherein said high-path resistive element has a resistance between 100 and 350 ohms.

19. The apparatus of claim 1 further including a feedback mechanism for stabilizing said analog output level in the course of transitions of said input digital signal across said threshold level

20. The apparatus of claim 19 wherein said feedback mechanism monitors said analog output level.

21. The apparatus of claim 19 wherein said feedback mechanism monitors said amplified high-path signal.

22. The apparatus of claim 19 wherein said feedback mechanism controls a level shift provided by said bit grouping providing system.

23. The apparatus of claim 19 wherein said feedback mechanism provides a feedback signal to said bit grouping providing system.

24. The apparatus of claim 19 wherein said feedback mechanism includes an analog-to-digital converter.

25. The apparatus of claim 1 wherein L+Lₛ=R_{L}.

26. The apparatus of claim 1 wherein L+Lₛ=R_{L}−1.

27. The apparatus of claim 1 wherein L+Lₛ=R_{L}−2.

28. The apparatus of claim 1 wherein K is 32, R_{L} is 24, R_{H} is 24, L is 18, and H is 14.

29. The apparatus of claim 1 wherein R_{L}=R_{H}.

30. The apparatus of claim 1 wherein L+H=J.

31. An apparatus for conversion of an input digital signal to an output analog signal having a maximum output level, said input digital signal being nominally a signal of K bits, comprising:
a bit grouping providing system which provides said input digital signal as a low-path digital signal of L bits, a middle-path digital signal of M bits, and a high-path digital signal of H bits, where L+M+H is greater than or equal to J, and J is a number of bits of said input digital signal utilized by said bit divider, where J is less than or equal to K,
a low-path digital-to-analog converter for digital inputs of R_{L} bits or less, said low-path digital signal being level shift mapped to an input of said low-path digital-to-analog converter, where L is less than or equal to R_{L}, wherein the L bits of the low-path digital signal are level shift mapped upwards by Lₛ bits where L+Lₛ≦R_{L}, said low-path digital-to-analog converter producing a low-path digital-to-analog converter output signal,
a middle-path digital-to-analog converter for digital inputs of R_{M} bits or less, said middle-path digital signal being level shift mapped to an input of said middle-path digital-to-analog converter, where M is less than or equal to R_{M}, said middle-path digital-to-analog converter producing a middle-path digital-to-analog converter output signal,
a high-path digital-to-analog converter for digital inputs of R_{H} bits or less, said high-path digital signal being bit shift mapped downwards to an input of said high-path digital-to-analog converter, where H is less than or equal to R_{H}, wherein the H bits of the low-path digital signal are level shift mapped downwards by Hₛ bits where (J−Hₛ)≦R_{H}, said high-path digital-to-analog converter producing a high-path digital-to-analog converter output signal,
a low-path attenuator which attenuates said low-path digital-to-analog converter output signal to produce an attenuated low-path analog signal,
a high-path amplifier which amplifies said high-path digital-to-analog converter output signal to produce an amplified high-path signal having a maximum level equal to said maximum output level, and
a passive summing node which, if a signal level characteristic of said input digital signal exceeds a first threshold level, sums a penultimate low-path signal derived from said attenuated low-path analog signal, a penultimate middle-path signal derived from said middle-path digital-to-analog converter output signal, and a penultimate high-path signal derived from said amplified high-path signal to produce said output analog signal, and if said signal level characteristic of said input digital signal exceeds a second threshold level but not said first threshold level, sums said penultimate low-path signal derived from said attenuated low-path analog signal and said penultimate middle-path signal derived from said middle-path digital-to-analog converter output signal to produce said output analog signal, and utilizes a means to reduce access of noise from said high-path amplifier to said passive summing node, and if said signal level characteristic of said input digital signal does not exceed said second threshold level, utilizes a means to reduce access of noise from said middle-path digital-to-analog converter output signal and said high-path amplifier to said passive summing node.

32. The apparatus of claim 31 wherein said bit grouping providing system is a bit divider which divides said input digital signal into said low-path digital signal, said middle-path digital signal, and said high-path digital signal.

33. The apparatus of claim 31 further including a feedback mechanism for stabilizing said analog output level in the course of transitions of said input digital signal across said first threshold level.

34. The apparatus of claim 31 further including a feedback mechanism for stabilizing said analog output level in the course of transitions of said input digital signal across said second threshold level.

35. An apparatus for conversion of an input digital signal to an output analog signal having a maximum output level, said input digital signal being nominally a signal of K bits, comprising:
a bit grouping providing system which provides said input digital signal as a low-path digital signal of L bits, a number n of middle-path digital signals of M₁, . . . , Mₙ bits, and a high-path digital signal of H bits, where L+M₁+ . . . +Mₙ+H is greater than or equal to J, and J is a number of bits of said input digital signal utilized by said bit divider, where J is less than or equal to K,
a low-path digital-to-analog converter for digital inputs of R_{L} bits or less, said low-path digital signal being level shift mapped to an input of said low-path digital-to-analog converter where L is less than or equal to R_{L}, wherein the L bits of the low-path digital signal are level shift mapped upwards by Lₛ bits where L+Lₛ≦R_{L}, said low-path digital-to-analog converter producing a low-path digital-to-analog converter output signal,
said number n of middle-path digital-to-analog converters for digital inputs of R_{M1}, . . . , R_{Mn} bits or less, said middle-path digital signals being level shift mapped to inputs of said middle-path digital-to-analog converter where M₁ . . . Mₙ are less than or equal to R_{M1}, . . . , R_{Mn}, respectively, said middle-path digital-to-analog converters producing middle-path digital-to-analog converter output signals,
a high-path digital-to-analog converter for digital inputs of R_{H} bits, said high-path digital signal being level shift mapped downwards to an input of said high-path digital-to-analog converter by a bit shift of Hₛ bits such that (J−Hₛ)≦R_{H}, said high-path digital-to-analog converter producing a high-path digital-to-analog converter output signal,
a low-path attenuator which attenuates said low-path digital-to-analog converter output signal to produce an attenuated low-path analog signal,
a high-path amplifier which amplifies said high-path digital-to-analog converter output signal to produce an amplified high-path signal having a maximum level equal to said maximum output level, and
a passive summing node which, if a signal level characteristic of said input digital signal exceeds a highest threshold level, sums a penultimate low-path signal derived from said attenuated low-path analog signal, penultimate middle-path signals derived from said middle-path digital-to-analog converter output signals, and a penultimate high-path signal derived from said amplified high-path signal to produce said output analog signal, and if said signal level characteristic of said input digital signal does not exceed a lowest threshold level, utilizes a means to reduce access of noise from said middle-path digital-to-analog converter output signals and said high-path amplifier to said passive summing node.

36. The apparatus of claim 35 wherein if said signal level characteristic of said input digital signal does not exceed an intermediate threshold level, sums said penultimate low-path signal derived from said attenuated low-path analog signal and penultimate middle-path signals which correspond to signal levels in said input digital signal below said signal level characteristic to produce said output analog signal, and utilizes a means to reduce access of noise to said passive summing node from said high-path amplifier and from penultimate middle-path signals which correspond to signal levels in said input digital signal above said signal level characteristic.

37. The apparatus of claim 35 further including a next-to-lowest-path attenuator which attenuates a next-to-lowest-path digital-to-analog converter output signal to produce an attenuated next-to-lowest-path analog signal.

38. The apparatus of claim 35 further including a next-to-highest-path amplifier which amplifies a next-to-highest-path digital-to-analog converter output signal to produce an amplified next-to-highest-path signal.

39. The apparatus of claim 35 further including a feedback mechanism for stabilizing said analog output level in the course of transitions of said input digital signal across said highest threshold level.

40. The apparatus of claim 35 further including a feedback mechanism for stabilizing said analog output level in the course of transitions of said input digital signal across said lowest threshold level.
